(19) United States
(12) Patent Application Publication
(10) Pub. No.: US 2015/0008507 A1
(43) Pub. Date: Jan. 8, 2015

(54) SEMICONDUCTOR DEVICE AND MANUFACTURING METHOD THEREOF

(71) Applicant: RENESAS ELECTRONICS CORPORATION, Kawasaki-shi (JP)

(72) Inventor: Yasufumi MORIMOTO, Ibaraki (JP)

(21) Appl. No.: 14/320,874

(22) Filed: Jul. 1, 2014

(30) Foreign Application Priority Data
Jul. 5, 2013 (JP) 2013-141637

(51) Int. Cl. H01L 27/11; H01L 21/28; H01L 21/283; H01L 27/092

(52) U.S. Cl. CPC H01L 27/1104; H01L 27/092; H01L 21/28026; H01L 21/283
USPC 257/324; 438/216

(57) ABSTRACT

Provided are a semiconductor device in which a data re-write operation can be performed a larger number of times and a data re-write operation is performed at a higher speed and a manufacturing method thereof. The semiconductor device includes a substrate, a first gate electrode, a second gate electrode, an insulating film, and a pair of source/drain regions. The first gate electrode is formed of a semiconductor layer containing an impurity of a first conductivity type. The second gate electrode is formed of a semiconductor layer containing an impurity of a second conductivity type. Each of the source/drain regions contains an impurity of the first conductivity type. The source region includes a first source region and a second source region having a concentration of the impurity of the first conductivity type higher than that of the first source region.

### CROSS-REFERENCE TO RELATED APPLICATIONS

The disclosure of Japanese Patent Application No. 2013-141637 filed on Jul. 5, 2013 including the specification, drawings and abstract is incorporated herein by reference in its entirety.

### BACKGROUND

The present invention relates to a semiconductor device and a manufacturing method thereof, and particularly to a manufacturing method of a semiconductor device having a MONOS flash memory including a plurality of gates.

Conceivable examples of a semiconductor device having an embedded flash memory or CPU (Central Processing Unit) include a microcomputer. For example, for a flash memory, a nonvolatile memory which is an element in which recorded information remains even when the power supply thereof is turned off is preferably used. By embedding the nonvolatile memory and a logic semiconductor device over the same semiconductor substrate, a microcomputer having a high function can be formed. The microcomputer in which the nonvolatile memory and the logic semiconductor device are placed is used widely in industrial machinery, home electric appliances, automobile-mounted devices, and the like.

In general, in a nonvolatile memory included in a microcomputer, a program needed by the microcomputer is stored and read as necessary to be used. Accordingly, a microcomputer in which a nonvolatile memory and a logic semiconductor device are embedded is used preferably. Examples of a nonvolatile memory appropriate for such embedment with a logic semiconductor device include a flash memory having a split-gate structure in which a control MIS (Metal Insulator Semiconductor) transistor and a storage MIS transistor are integrally formed.

As the flash memory having the split-gate structure, e.g., a MONOS flash memory using MONOS (Metal Oxide Nitride Oxide Silicon) for the storage MIS transistor is used. In the MONOS flash memory, a memory gate electrode as the gate electrode of the storage transistor containing an n-type impurity is typically used. The flash memory including the n-type memory gate electrode is capable of a high-speed operation and has high reliability. The flash memory including the n-type memory gate is used widely for an application in a high-end region, such as, e.g., a vehicle-mounted MCU (Micro Controller Unit).

To apply the MONOS flash memory to a low-end region and a middle-end region, it is requested to develop a device at cost lower than that of a related-art MONOS flash memory. To respond to the request, the development of a memory gate electrode containing a p-type impurity has been promoted. A flash memory including a p-type memory gate electrode is disclosed in, e.g., Japanese Unexamined Patent Publication No. 2012-114269 (Patent Document 1).

In the MONOS flash memory including the n-type memory gate electrode, during each of a data write operation and a data erase operation, electrons or holes need to be moved so as to pass through the one of a plurality of stacked layers of insulating films located on the semiconductor substrate side (underside) of the memory gate electrode which is closest to the semiconductor substrate (lowermost layer). This may degrade the lifetime of the lowermost-layer insulating film and reduce the number of times a re-write operation can be performed to the MONOS flash memory.

On the other hand, in the MONOS flash memory including the p-type memory gate electrode, electrons are moved so as to pass through the foregoing lowermost-layer insulating film during a data write operation but, during a data erase operation, holes are moved so as to pass through the one of the plurality of stacked layers of insulating films located on the semiconductor substrate side (underside) of the memory gate electrode which is closest to the memory gate electrode (uppermost layer). This gives no damage to the foregoing lowermost-layer insulating film. Accordingly, it is possible to increase the number of times a data write operation and a data erase operation can be repeatedly performed to the foregoing insulating film.

### RELATED ART DOCUMENT

### Patent Document

### [Patent Document 1]

Japanese Unexamined Patent Publication No. 2012-114269

### SUMMARY

In Patent Document 1, the p-type memory gate electrode is formed first, and then n-type source/drain regions are formed. In this case, if the source/drain regions are formed by, e.g., implanting an n-type impurity into the semiconductor substrate using the memory gate electrode as a mask, the n-type impurity is implanted into the p-type memory gate electrode to offset the concentration of the p-type impurity implanted in the memory gate electrode. This significantly reduces the concentration of the p-type impurity in the memory gate electrode and may possibly impair the function of the memory gate electrode. It may also be possible that a part of the n-type impurity implanted in the memory gate electrode passes through the memory gate electrode to enter the semiconductor substrate located thereunder. This is because the memory gate electrode has a thickness smaller than that of the control gate electrode as the gate electrode of the control transistor so that the distance the impurity needs to travel to pass through the memory gate electrode is shorter.

The memory gate has not only a small thickness but also a shape in which the uppermost surface thereof is inclined. Accordingly, it is difficult to form, e.g., a photoresist having the same end surface as that of the memory gate electrode into a pattern with high accuracy. Therefore, it is difficult to implant the n-type impurity for the source region into a region in the semiconductor substrate which is located externally of the memory gate electrode in a state where the memory gate electrode is covered with the photoresist.

For the reason described above, in Patent Document 1, the source region in the semiconductor substrate which is located externally of the memory gate electrode is formed only of a low-concentration impurity diffusion layer.

In the MONOS flush memory thus having only the source region which is the low-concentration impurity diffusion layer, an electric characteristic (e.g., so-called I-V characteristic) is degraded and the electric resistance is high so that I is unlikely to increase in proportion to the magnitude of V. When the I-V characteristic is degraded to reduce a current value, the drive speed of the MONOS flash memory decreases to reduce a data rewrite speed. This may degrade the performance of the MONOS flash memory.

There is a concern that, in the source region in Patent Document 1, the intensity of an electric field increases in the low-concentration impurity diffusion layer to increase a leakage current (junction leakage) in the junction portion between the source region and the semiconductor substrate. When the junction leakage is increased, a current during a data write (rewrite) operation to the MONOS flash memory undergoes a loss, which may possibly reduce a data write speed.

Other problems and novel features of the present invention will become apparent from a statement in the present specification and the accompanying drawings.

A semiconductor device according to an embodiment includes a semiconductor substrate, a first gate electrode, a second gate electrode, an insulating film, and a pair of source/drain regions. The first gate electrode is formed of a semiconductor layer containing an impurity of a first conductivity type. The second gate electrode is formed of a semiconductor layer containing an impurity of a second conductivity type. Each of the source/drain regions contains an impurity of the first conductivity type. The source region includes a first source region, and a second source region having a concentration of the first-conductivity-type impurity higher than that of the first source region.

In a method of manufacturing the semiconductor device according to the embodiment, the semiconductor substrate is provided first and, over a main surface thereof, the first gate electrode and a dummy gate electrode are formed. Using the foregoing dummy gate electrode as a mask, the source region is formed in the main surface. After the foregoing dummy gate electrode is removed, the second gate electrode is formed. In a state where the foregoing second gate electrode is covered, the drain region is formed in the main surface. Into a semiconductor film intended to serve as the first gate electrode, the impurity of the first conductivity type is introduced and, into a semiconductor film intended to serve as the second gate electrode, the impurity of the second conductivity type is introduced. When the foregoing source and drain regions are formed, the impurity of the first conductivity type is implanted into the semiconductor substrate. When the foregoing source region is formed, the first source region and the second source region having the concentration of the impurity of the first conductivity type higher than that of the first source region are formed.

The semiconductor device of the embodiment and the manufacturing method thereof allow a semiconductor device to be provided in which a data re-write operation can be performed a larger number of times and a data re-write operation is performed at a higher speed.

### BRIEF DESCRIPTION OF THE DRAWINGS

FIG. 1 is a schematic cross-sectional view showing the forms of a memory cell region and a peripheral circuit region in a semiconductor device having a MONOS flash memory of an embodiment;

FIG. 2 is a schematic cross-sectional view showing a configuration of a memory gate insulating film in the MONOS flash memory of FIG. 1;

FIG. 3A is a schematic cross-sectional view clearly showing a region showing a lateral impurity concentration distribution in a source region in the semiconductor device of the embodiment with a graph showing the impurity concentration distribution in the region, and FIG. 3B is a schematic cross-sectional view clearly showing a region showing a lateral impurity concentration distribution in a source region in a semiconductor device of a comparative example with a graph showing the impurity concentration distribution in the region;

FIG. 4A is a schematic cross-sectional view clearly showing a region showing a longitudinal impurity concentration distribution in the source region in the semiconductor device of the embodiment with a graph showing the impurity concentration distribution in the region, and FIG. 4B is a schematic cross-sectional view clearly showing a region showing a longitudinal impurity concentration distribution in the source region in the semiconductor device of the comparative example with a graph showing the impurity concentration distribution in the region;

FIG. 5 is a schematic cross-sectional view showing a first step of a manufacturing method of the semiconductor device in the embodiment;

FIG. 6 is a schematic cross-sectional view showing a second step of the manufacturing method of the semiconductor device in the embodiment;

FIG. 7 is a schematic cross-sectional view showing a third step of the manufacturing method of the semiconductor device in the embodiment;

FIG. 8 is a schematic cross-sectional view showing a fourth step of the manufacturing method of the semiconductor device in the embodiment;

FIG. 9 is a schematic cross-sectional view showing a fifth step of the manufacturing method of the semiconductor device in the embodiment;

FIG. 10 is a schematic cross-sectional view showing a sixth step of the manufacturing method of the semiconductor device in the embodiment;

FIG. 11 is a schematic cross-sectional view showing a seventh step of the manufacturing method of the semiconductor device in the embodiment;

FIG. 12 is a schematic cross-sectional view showing an eighth step of the manufacturing method of the semiconductor device in the embodiment;

FIG. 13 is a schematic cross-sectional view showing a ninth step of the manufacturing method of the semiconductor device in the embodiment;

FIG. 14 is a schematic cross-sectional view showing a tenth step of the manufacturing method of the semiconductor device in the embodiment;

FIG. 15 is a schematic cross-sectional view showing an eleventh step of the manufacturing method of the semiconductor device in the embodiment;

FIG. 16 is a schematic cross-sectional view showing a twelfth step of the manufacturing method of the semiconductor device in the embodiment;

FIG. 17 is a schematic cross-sectional view showing a thirteenth step of the manufacturing method of the semiconductor device in the embodiment;

FIG. 18 is a schematic cross-sectional view showing a fourteenth step of the manufacturing method of the semiconductor device in the embodiment;

FIG. 19A is a schematic cross-sectional view showing a data write operation to a MONOS memory cell of the comparative example and FIG. 19B is a schematic cross-sectional view showing a data erase operation to the MONOS memory cell of the comparative example;

FIG. 20A is a schematic cross-sectional view showing a data write operation to a MONOS memory cell of the embodiment and FIG. 20B is a schematic cross-sectional view showing a data erase operation to the MONOS memory cell of the embodiment; and

FIG. 21A is an energy band diagram of a MONOS structure of the comparative example and FIG. 21B is an energy band diagram of the MONOS structure of the embodiment.

### DETAILED DESCRIPTION

An embodiment will be described below on the basis of the drawings. First, a description will be given of a configuration of a semiconductor device of the embodiment.

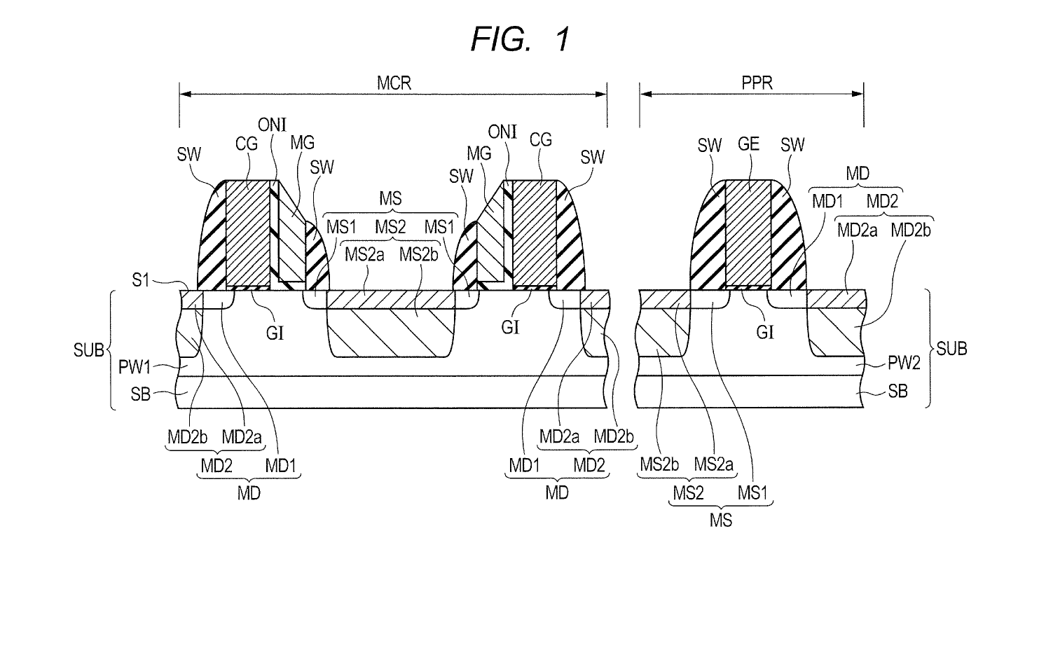

Referring to FIG. 1, the semiconductor device of the embodiment has a memory cell region MCR and a peripheral circuit region PPR. The memory cell region MCR and the peripheral circuit region PPR are formed in a semiconductor substrate SUB having a main surface S1. More specifically, the memory cell region MCR is formed in a p-type well region PW1 formed in the main surface S1 of the semiconductor substrate SUB, while the peripheral circuit region PPR is formed in a p-type well region PW2 formed in the main surface S1 of a substrate main body SB made of, e.g., a single crystal of silicon and serving as the main body of the semiconductor substrate SUB.

In the memory cell region MCR, e.g., a flash memory is formed as a nonvolatile memory. The flash memory is a MONOS flash memory which has a split-gate structure and in which two transistors, i.e., a control transistor having a control gate electrode CG as the gate electrode thereof and a storage transistor having a memory gate electrode MG as the gate electrode thereof are coupled to each other.

FIG. 1 shows a form in which, in the memory cell region MCR, the two memory cells of the MONOS flash memory are placed to be spaced apart from each other. Each of the memory cells (of the MONOS flash memory) has a source region MS and a drain region MD which are formed in the main surface S1 of the semiconductor substrate SUB to be spaced apart from each other. The foregoing two memory cells share the source region MS. On the left and right sides of FIG. 1, an isolation insulating film for providing, e.g., electrical insulation between a plurality of memory cells is formed, though not shown in FIG. 1.

Each of the memory cells has a control gate insulating film GI formed over the main surface S1 of the semiconductor substrate SUB and the control gate electrode CG. The control gate insulating film GI and the control gate electrode CG form the control transistor. Each of the memory cells also has a memory gate insulating film ONI formed over the main surface S1 of the semiconductor substrate SUB and the memory gate electrode MG. The memory gate insulating film ONI and the memory gate electrode MG form the storage transistor. Each of the memory cells also has sidewall insulating films SW formed over the main surface S1 so as to cover the side surfaces of the control gate electrode CG and the memory gate electrode MG.

Note that the two memory cells in FIG. 1 are arranged such that the respective memory gate electrodes MG thereof face each other. Since the drain regions MD are formed on the side where each of the control gate electrodes CG is located and the source region MS is formed on the side where each of the memory gate electrodes MG is located, the foregoing two memory cells share the source region MS formed on the side where each of the pair of memory gate electrodes MG facing each other is located.

Each of the control gate insulating films GI is formed of the same material as that of a gate insulating film in a typical MOS (Metal Oxide Semiconductor) transistor, such as a silicon oxide film. The control gate insulating film GI is formed so as to enhance the adhesion between the semiconductor substrate SUB and the control gate electrode CG and suppress interface states.

Each of the control gate electrodes CG as a first gate electrode performs read/write/erase operations and is formed of a thin film of polysilicon (semiconductor layer) containing a generally known n-type impurity (impurity of a first conductivity type).

Each of the memory gate electrodes MG as a second gate electrode performs write/erase flash operations and is located so as to be adjacent to the control gate electrode CG in the memory cell. The memory gate electrode MG is formed of a thin film of polysilicon (semiconductor layer) containing a generally known p-type impurity (impurity of a second conductivity type).

The control gate electrode CG is formed such that the uppermost surface thereof most distant from the semiconductor substrate SUB extends in a direction generally along the main surface S1 of the semiconductor substrate SUB. Accordingly, the thickness of the control gate electrode CG in the thickness direction of the semiconductor substrate SUB is substantially constant irrespective of the position at which the control gate electrode CG is formed. On the other hand, the uppermost surface of the memory gate electrode MG most distant from the semiconductor substrate SUB may extend in a direction along the main surface S1 of the semiconductor substrate SUB or may also have a cross-sectional shape which is inclined with distance from the control gate electrode CG toward the semiconductor substrate SUB, as shown in FIG. 1. Accordingly, the memory gate electrode MG may also have a shape in which the thickness thereof in the thickness direction of the semiconductor substrate SUB decreases with distance from the control gate electrode CG (i.e., shape similar to that of each of the sidewall insulating films SW).

The memory gate insulating film ONI (insulating film) extends from a region interposed between the memory gate electrode MG and the semiconductor substrate SUB in continuous relation to a region interposed between the control gate electrode CG and the memory gate electrode MG. That is, the memory gate insulating film ONI is bent such that the extending direction thereof changes (e.g., about) 90° between the region interposed between the memory gate electrode MG and the semiconductor substrate SUB and the region interposed between the control gate electrode CG and the memory gate electrode MG.

The pair of source region MS and the drain region MD are formed such that at least a channel region (in the semiconductor substrate SUB, i.e., in the p-type well region PW1) immediately under the control gate electrode CG (and the control gate insulating film GI) is interposed therebetween. That is, the control gate electrode CG on the left-hand side of FIG. 1 is interposed between the drain region MD on the left side thereof and the source region MS on the right side thereof. The control gate electrode CG on the right-hand side of FIG. 1 is interposed between the source region MS on the left side thereof and the drain region MD on the right side thereof.

Sidewall insulating films SW include the drain-side sidewall insulating films SW each formed on the side of the control gate electrodes CG where the drain regions MD are located so as to cover the side surfaces of the control gate electrodes CG (so as to be adjacent to the control gate electrodes CG) and the source-side sidewall insulating films SW each formed on the side of the memory gate electrodes MG where the source regions MS are located so as to cover the side surfaces of the memory gate electrodes MG (so as to be adjacent to the memory gate electrodes MG). Each of the sidewall insulating films SW is preferably formed of, e.g., a silicon nitride film, but may also have a laminate structure including a silicon oxide film and a silicon nitride film.

The source region MS is formed on the side of the two memory cells where the memory gate electrodes MG facing each other are located and includes lower-concentration source regions MS1 each as a first source region and a higher-concentration source region MS2 as a second source region. The lower-concentration source regions MS1 and the higher-concentration source region MS2 are impurity diffusion regions each formed in the p-type well region PW1 and containing a first-conductivity-type, i.e., n-type impurity.

The lower-concentration source regions MS1 are located generally immediately under the source-side sidewall insulating films SW. The higher-concentration source region MS2 is formed in the region adjacent to the lower-concentration source regions MS1 in a direction generally along the main surface S1 of the semiconductor substrate SUB. In other words, the higher-concentration source region MS2 is located externally of the source-side sidewall insulating films SW. That is to say, the higher-concentration source region MS2 is formed in the region generally interposed between the two lower-concentration source regions MS1 and in the p-type well region PW1 immediately under the region generally interposed between the two source-side sidewall insulating films SW facing each other. In the present embodiment, the source region MS and the drain regions MD are formed such that the channel regions immediately under the control gate electrodes CG and the memory gate electrodes MG are interposed therebetween.

The higher-concentration source region MS2 includes an upper source region MS2a and a lower source region MS2b. The upper source region 2a is formed between the two lower-concentration source regions MS1. The depth of the upper source region MS2a in the thickness direction (vertical direction in FIG. 1) of the semiconductor substrate SUB is substantially equal to the foregoing depth of each of the lower-concentration source regions MS1. The lower source region MS2b is formed in the region interposed between the two lower-concentration source regions MS1 so as to come in contact with the lower surface (on the side where the substrate main body SB is located) of the upper source region MS2a.

That is, the lower source region MS2b is formed at a position more distant (in the downward direction in the drawing) from the main surface S1 of the semiconductor substrate SUB than that of the upper source region MS2a. In general, the thickness (in the vertical direction in the drawing) of the lower source region MS2b is preferably larger than the thickness of the upper source region MS2a, but it is not limited thereto. Since the higher-concentration source region MS2 has the configuration in which the two source regions MS2a and MS2b are thus stacked in the vertical direction in the drawing, the higher-concentration source region MS2 is formed thicker (deeper) in the vertical direction in the drawing than the lower-concentration source regions MS1.

Each of the drain regions MD is formed on the side of each of the memory cells where the control gate electrode CG is located and has a lower-concentration drain region MD1 as a first drain region and a higher-concentration drain region MD2 as a second drain region. The lower-concentration drain region MD1 and the higher-concentration drain region MD2 are impurity diffusion regions each formed in the p-type well PW1 and containing an impurity of n-type as a first conductivity type.

The lower-concentration drain regions MD1 are formed in the p-type well region PW1 generally immediately under the drain-side sidewall insulating films SW. The higher-concentration drain regions MD2 are formed in the regions adjacent to the lower-concentration drain regions MD1 in a direction generally along the main surface S1 of the semiconductor substrate SUB. In other words, the higher-concentration drain regions MD2 are located externally of the drain-side sidewall insulating films SW.

Each of the higher-concentration drain regions MD2 has an upper drain region MD2a and a lower drain region MD2b. The upper drain region MD2 is formed in the region adjacent to the lower-concentration drain region MD1 in the direction along the main surface S1 of the semiconductor substrate SUB. The depth of the upper drain region MD2a in the thickness direction (vertical direction in FIG. 1) of the semiconductor substrate SUB is substantially equal to the foregoing depth of each of the lower-concentration drain regions MD1. The lower drain region MD2b is formed in the region adjacent to the lower-concentration drain region MD1 so as to come in contact with the lower surface (on the side where the substrate main body SB is located) of the upper drain region MD2a.

That is, the lower drain region MD2b is formed at a position more distant (in the downward direction in the drawing) from the main surface S1 of the semiconductor substrate SUB than that of the upper drain region MD2a. In general, the thickness (in the vertical direction in the drawing) of the lower drain region MD2b is preferably larger than the thickness of the upper drain region MD2a, but it is not limited thereto. Since the higher-concentration drain region MD2 has the configuration in which the two drain regions MD2a and MD2b are thus stacked in the vertical direction in the drawing, the higher-concentration drain region MD2 is formed thicker (deeper) in the vertical direction in the drawing than the lower-concentration drain region MD1.

On the other hand, in the peripheral circuit region PPR, a peripheral circuit for driving a nonvolatile memory (MONOS flash memory) is formed and n-channel MISFETs (Metal Insulator Semiconductor Field Effect Transistors) or the like are formed.

On the left and right sides of each of the MISFETs in the peripheral circuit region PPR, an isolation insulating film not shown is formed to provide electrical insulation between the plurality of MISFETs. Each of the MISFETs has the source region MS and the drain region MD which are formed in the main surface S1 of the semiconductor substrate SUB to be spaced apart from each other and further has the gate insulating film GI formed over the main surface S1 of the semiconductor substrate SUB, a gate electrode GE, and the sidewall insulating films SW. The gate electrode GE is formed over the main surface S1 of the semiconductor substrate SUB interposed between the source region MS and the drain region MD with the gate insulating film GI being interposed therebetween.

The source region MS and the drain region MD are impurity diffusion regions each formed in the p-type well region PW2 of the semiconductor substrate SUB and containing an impurity of the first conductivity type, i.e., n-type. The source region MS includes the lower-concentration source region MS1 and the higher-concentration source region MS2. The drain region MD includes the lower-concentration drain region MD1 and the higher-concentration drain region MD2.

The lower-concentration source region MS1 and the lower-concentration drain region MD1 are formed generally immediately under the sidewall insulating films SW. The higher-concentration source region MS2 and the higher-concentration drain region MD2 are formed externally of the sidewall insulating films SW so as to be respectively adjacent to the lower-concentration source region MS1 and the lower-concentration drain region MD1.

In each of the MISFETs in the peripheral circuit also, in the same manner as in the memory cells, the higher-concentration source region M2 includes the upper source region MS2a and the lower source region MS2b, which are arranged basically similarly to the upper source region MS2a and the like in the memory cells. In each of the MISFETs in the peripheral circuit also, in the same manner as in the memory cells, the higher-concentration drain region MD2 includes the upper drain region MD2a and the lower drain region MD2, which are arranged basically similarly to the upper drain region MD2a and the like in the memory cells.

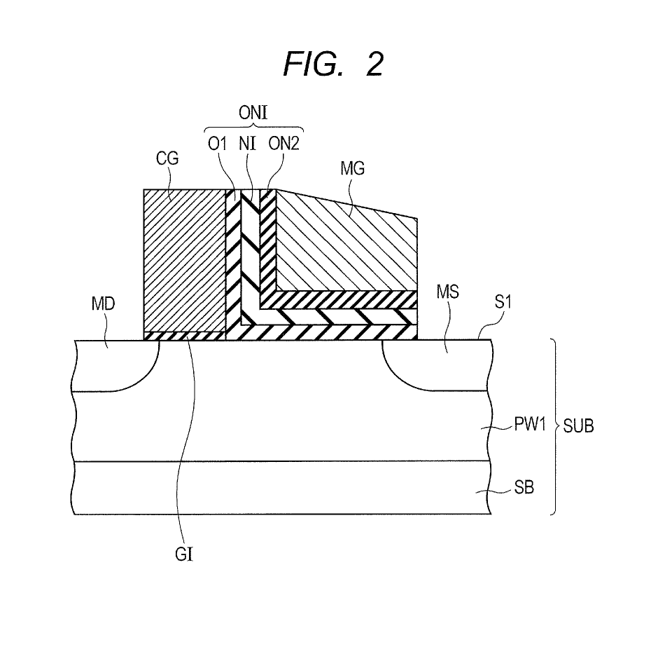

Referring to FIG. 2, the memory gate insulating films ONI have a structure in which a first insulating film O1 formed so as to come in contact with the side surface of the control gate electrode CG and the main surface S1 of the semiconductor substrate SUB, a second insulating film NI formed so as to cover the upper surface of the first insulating film O1, and a third insulating film ON2 formed so as to cover the upper surface of the second insulating film NI are stacked in this order. Here, the upper surface of the first insulating film O1 means the surface of the first insulating film O1 opposite to the side surface of the control gate electrode CG and the main surface S1 of the semiconductor substrate SUB. The upper surface of the second insulating film NI means the surface of the second insulating film NI opposite to the first insulating film O1.

The first insulating film O1 preferably includes, e.g., a silicon oxide film. The second insulating film NI preferably includes, e.g., a silicon nitride film. The third insulating film ON2 preferably includes, e.g., a silicon oxide film, or more preferably is a so-called silicon oxynitride film as a silicon oxide film containing nitrogen.

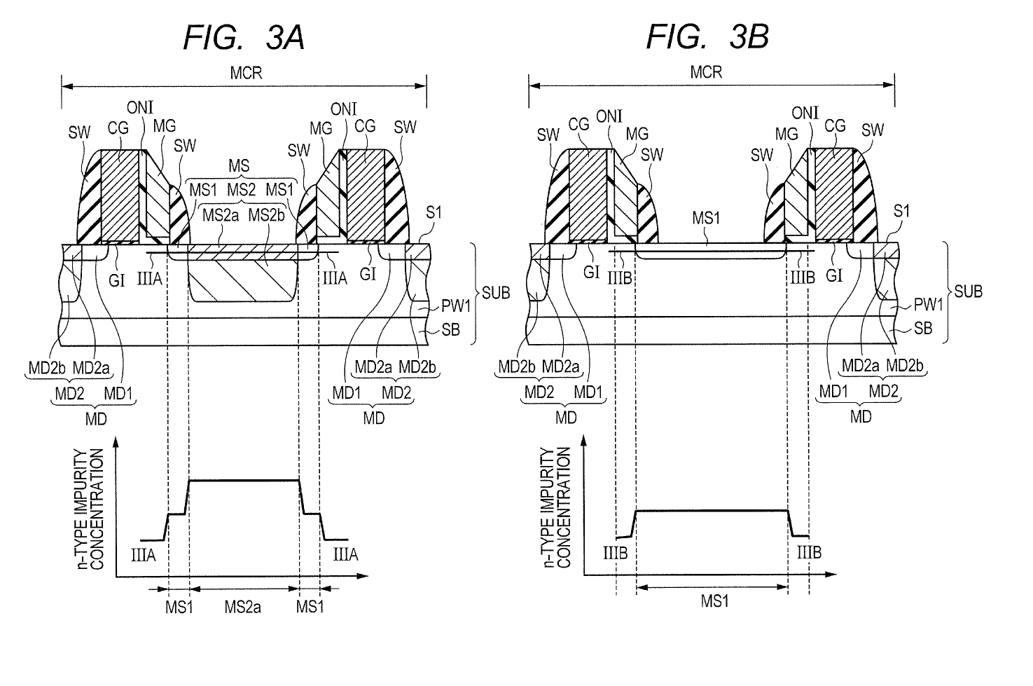

Referring to FIGS. 3A and 3B, the portion along the line IIIA-IIIA and the portion along the line IIIB-IIIB each shown in the schematic cross-sectional views of the semiconductor device clearly show regions showing impurity concentrations. The source region MS of each of the memory cells in the present embodiment has a configuration including the lower-concentration source region MS1 as the first source region and the higher-concentration source region MS2 as the second source region having the first-conductivity-type (n-type) impurity concentration higher than that of the lower-concentration source region MS1. That is, unlike in the case where the source region MS is configured to include only the single low-concentration source region MS1 as shown in, e.g., FIG. 3B, in the memory cell in the present embodiment, the source region MS of each of the memory cells in the present embodiment has the two source regions MS1 and MS2a having different n-type impurity concentrations, as shown in FIG. 3A.

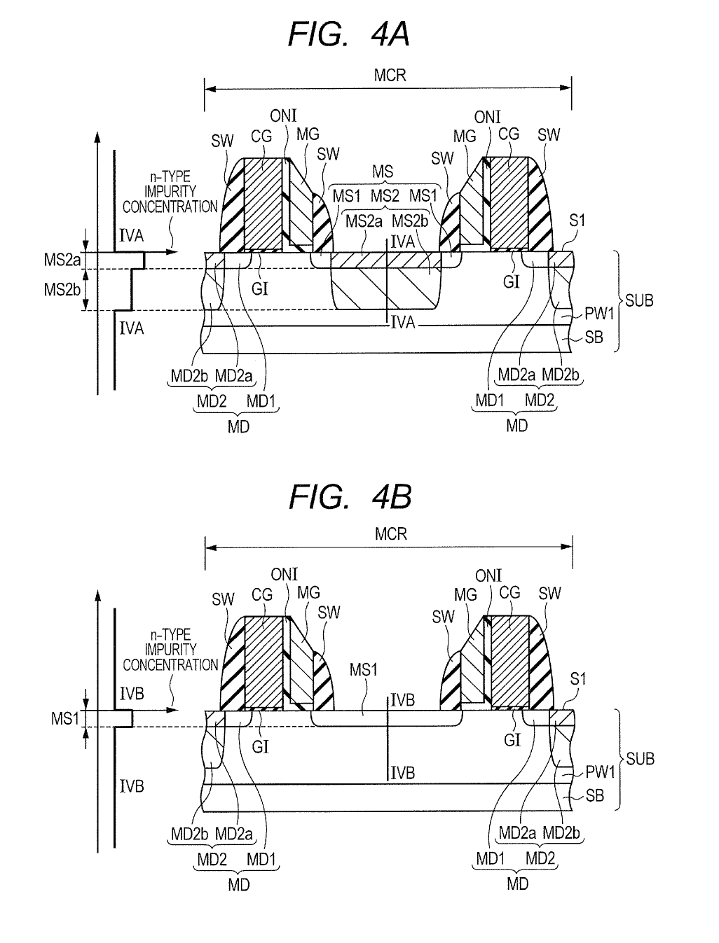

FIGS. 3A and 3B show that the source region MS has the two impurity regions MS1 and MS2a having different impurity concentrations in the lateral direction along the main surface S1 of the semiconductor substrate SUB. However, referring to FIGS. 4A and 4B, the source region MS of the memory cell in the present embodiment also has the two impurity regions MS2a and MS2b having different impurity concentrations even in a vertical direction crossing the main surface S1 of the semiconductor substrate SUB. The n-type impurity concentration of the upper source region MS2a is higher than the n-type impurity concentration of the lower source region MS2b. On the other hand, the n-type impurity concentration of the lower source region MS2b is higher than the n-type impurity concentration of the lower-concentration source region MS1.

It is considered that, in FIG. 4, in the vertical direction crossing the foregoing main surface S1, the upper source region MS2a formed externally of the memory gate electrode MG (particularly externally of the source-side sidewall insulating film SW herein) is the foregoing second source region (region having the impurity concentration higher than that of the first source region) and the lower source region MS2b located so as to come in contact with the lower surface of the upper source region MS2a is the foregoing first source region (region having the impurity concentration lower than that of the second source region). Due to such consideration, it can be said that, in the foregoing vertical direction of the source region also, the second source region has the n-type impurity concentration higher than that of the first source region.

Note that, similarly to the source region MS, the drain region MD in the present embodiment also has a configuration including two regions having different impurity concentrations which are the lower-concentration drain region MD1 (first drain region) and the higher-concentration drain region MD2 (second drain region) having the first-conductivity-type (n-type) impurity concentration higher than that of the lower-concentration drain region MD1 in the lateral direction along the main surface S1 of the semiconductor substrate SUB, though not shown in such graphs as in FIGS. 3A, 3B, 4A, and 4B.

In the vertical direction crossing the main surface S1 of the drain region MD also, similarly to the source region MS, the drain region MD has a configuration including two regions having different impurity concentrations which are the lower drain region MD2b and the upper drain region MD2a having the first-conductivity-type (n-type) impurity concentration higher than that of the lower drain region MD2b. That is, it is considered that the upper drain region MD2a formed externally of the control gate electrode CG is the foregoing second drain region (region having the impurity concentration higher than that of the first drain region) and the lower drain region MD2b located so as to come in contact with the lower surface of the upper drain region MD2a is the foregoing first drain region (region having the impurity concentration lower than that of the second drain region). Due to such consideration, it can be said that, in the foregoing vertical direction of the drain region also, the second drain region has the n-type impurity concentration higher than that of the first drain region.

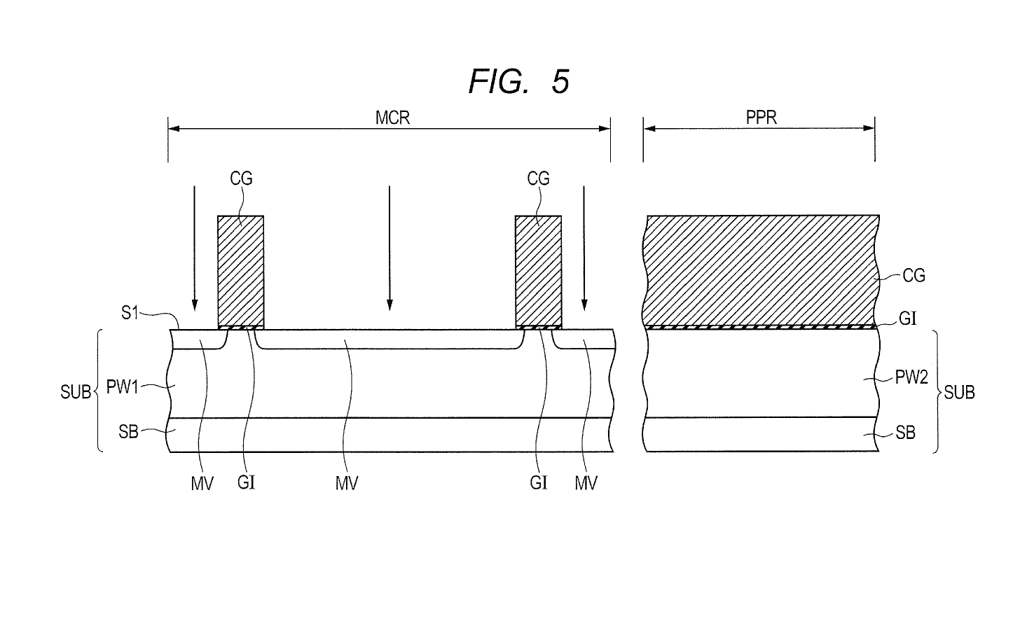

Next, referring to FIGS. 5 to 18, a description will be given of a manufacturing method of the semiconductor device of the foregoing embodiment.

Referring to FIG. 5, the semiconductor substrate SUB having main surfaces is provided first. Specifically, the substrate main body SB made of a single crystal of silicon having, e.g., a p-type impurity is provided. In one of the main surfaces (on the upper side in the drawing), the p-type well regions PW1 and PW2 are formed using a typical photoengraving technique and an ion implantation technique. Thus, the semiconductor substrate SUB is formed in which, in the main surface S1 of the substrate main body SB, the p-type well regions PW1 and PW2 are formed.

In the memory cell region MCR where the memory cells are to be formed eventually, over the p-type well region PW1, an insulating film made of a silicon oxide film is formed by a typical thermal oxidation method. Then, a thin film of polysilicon containing an n-type impurity (e.g., arsenic or phosphorus) is formed to a thickness of not less than 100 nm and not more than 300 nm by a typical CVD (Chemical Vapor Deposition) method so as to cover the upper surface of the insulating film. Then, by a typical photoengraving technique and etching, the foregoing thin film of polysilicon and the insulating film immediately thereunder are patterned to form the control gate electrodes CG and the gate insulating films GI immediately thereunder.

Note that, here, in the case of introducing an n-type impurity into the thin film of polysilicon to be deposited, when, e.g., the thin film CG of polysilicon which is a semiconductor film intended to serve as the control gate electrodes CG is formed, the first-conductivity-type (n-type) impurity is ion-implanted in the thin film. However, by causing a gas for deposition to include a doping gas (gas for adding the n-type impurity), the thin film of polysilicon containing the n-type impurity can be formed. It may also be possible that, during the formation of the thin film, a thin film of amorphous silicon is deposited first and then subjected to heat treatment to be crystallized. That is, here, using an ion implantation technique or a method other than the ion implantation technique, when the thin film CG of polysilicon which is the semiconductor film intended to serve as the control gate electrodes CG is formed, the first-conductivity-type (n-type) impurity can be introduced into the thin film.

In the peripheral circuit region PPR where the MISFETs each as the peripheral circuit are to be formed eventually also, in the same manner as in the memory cell region MCR, over the p-type well region PW2, the insulating film GI and the thin film CG of polysilicon are formed, but need not necessarily be patterned herein.

Next, using the control gate electrodes CG in the memory cell region MCR as a mask, an impurity region MV is formed in the main surface of the semiconductor substrate SUB except for the portions thereof located immediately under the control gate electrodes CG in accordance with a self-alignment technique using a typical ion implantation technique. Here, the impurity region MV having a relatively low impurity concentration is preferably formed through the implantation of an n-type impurity. The impurity region MV is formed so as to adjust threshold voltages/currents in the regions located immediately under the memory gate electrodes MG formed later. However, since the impurity region MV need not necessarily be formed, the illustration of the impurity region MV is omitted in each of the subsequent drawings.

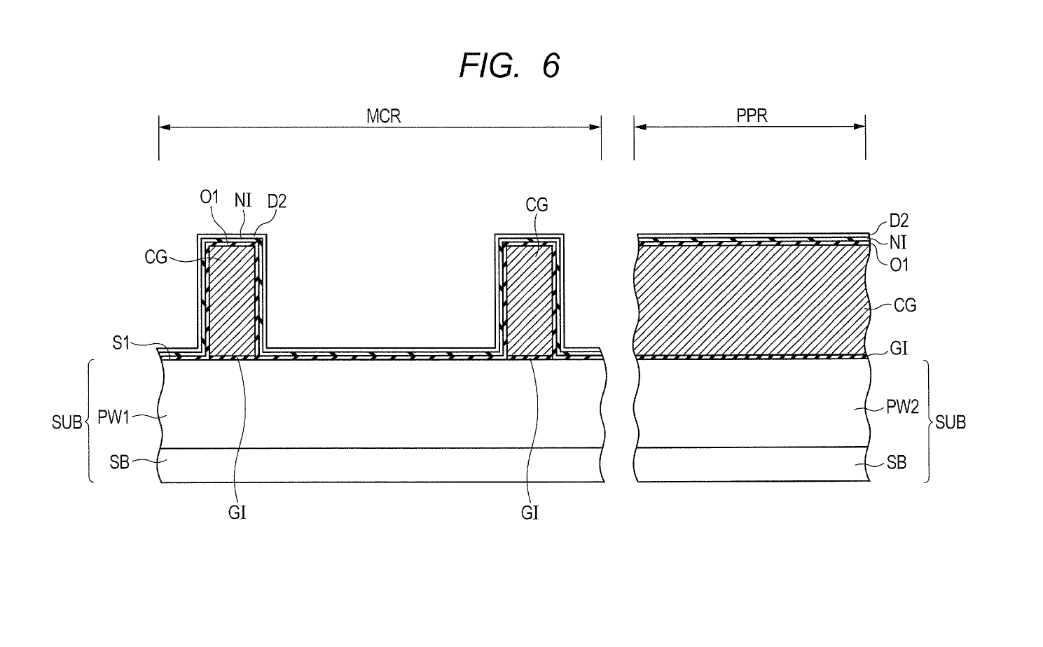

Referring to FIG. 6, over the main surface S1 of the semiconductor substrate SUB, the first insulating film O1 including the silicon oxide film, the second insulating film NI including the silicon nitride film, and a dummy insulating film D2 including a silicon oxide film are stacked in this order into three layers so as to cover the upper surfaces and side surfaces of the control gate electrodes CG formed in the memory cell region MCR. The second insulating film NI is formed so as to cover the upper surface of the first insulating film O1. The dummy insulating film D2 is formed so as to cover the upper surface of the second insulating film NI. These insulating films O1, NI, and D2 are formed by, e.g., a typical CVD method.

In the peripheral circuit region PPR, the foregoing first insulating film O1, second insulating film NI, and dummy insulating film D2 are formed so as to cover the upper surface of the thin film CG of polysilicon.

Note that the foregoing first insulating film O1 is preferably formed to have a thickness of not less than 3 nm and not more than 6 nm, the second insulating film NI is preferably formed to have a thickness of not less than 5 nm and not more than 10 nm, and the dummy insulating film D2 is preferably formed to have a thickness of not less than 4 nm and not more than 7 nm.

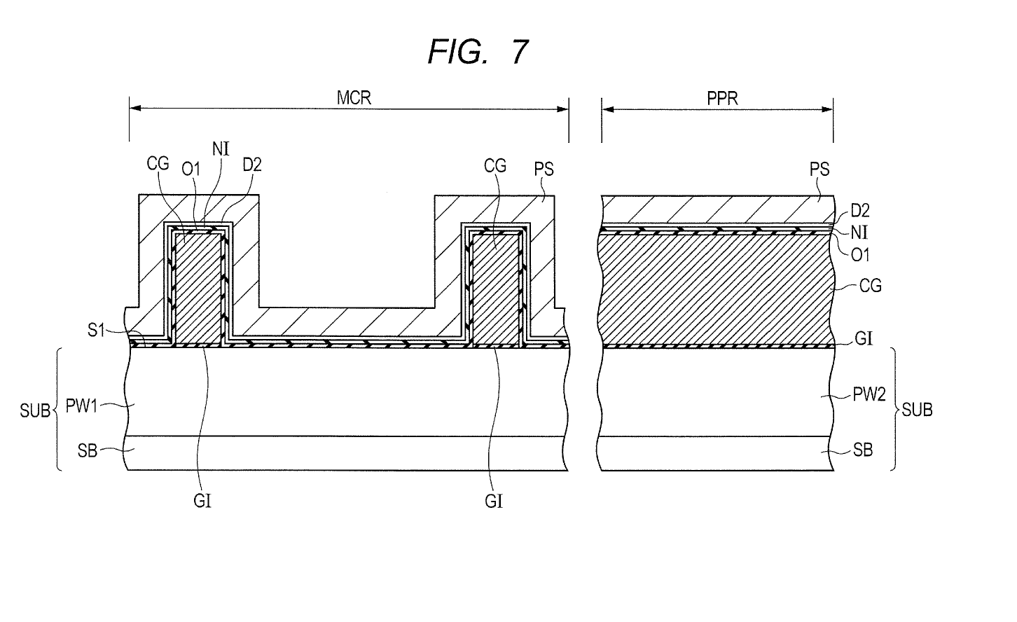

Referring to FIG. 7, in the memory cell region MCR, a silicon thin film PS intended to serve as a dummy gate is formed so as to cover the entire upper surface of the dummy insulating film D2 in the uppermost layer of the insulating films stacked so as to cover the upper surfaces and side surfaces of the control gate electrodes CG. In the peripheral circuit region PPR also, the silicon thin film PS is formed so as to cover the entire upper surface of the dummy insulating film D2. The silicon thin film PS may be either a thin film of polysilicon containing no conductive impurity or a thin film of amorphous (non-crystalline) silicon. The silicon thin film PS is preferably formed by a typical CVD method.

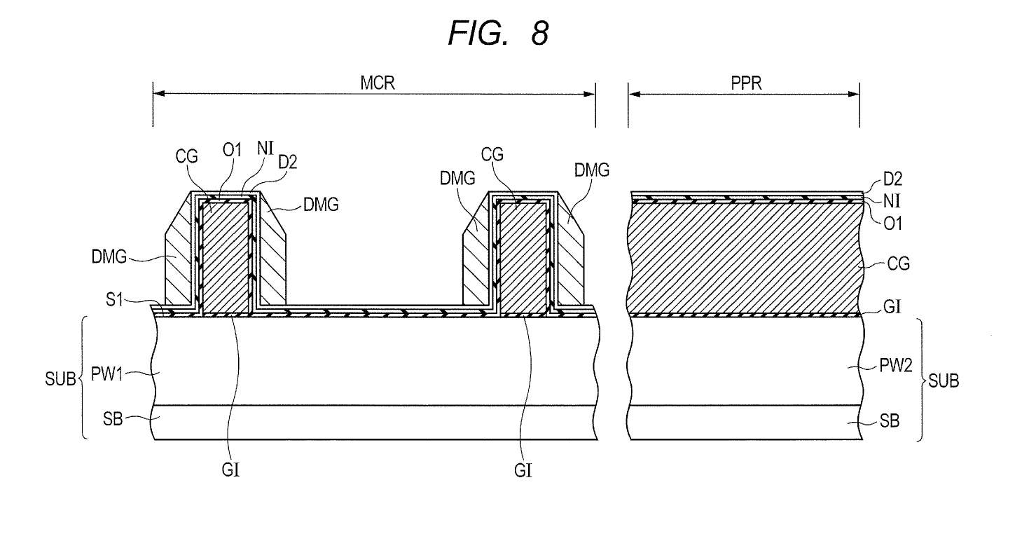

Referring to FIG. 8, anisotropic drying etching is performed using the dummy insulating film D2 in the uppermost layer (layer most distant from the semiconductor substrate SUB) forming the stacked insulating films as an etching stopper to etch back the silicon thin film PS. As a result, in the memory cell region MCR, dummy gate electrodes DMG are formed so as to be adjacent to the control gate electrodes CG (more specifically, so as to come in contact with the dummy insulating film D2 over the side surfaces of the control gate electrodes CG). The dummy gate electrodes DMG are each formed to have a thickness in the vertical direction in the drawing which decreases with distance from the control gate electrodes CG (outwardly from the control gate electrodes CG). Note that the silicon thin film PS in the peripheral circuit region PPR is etched away.

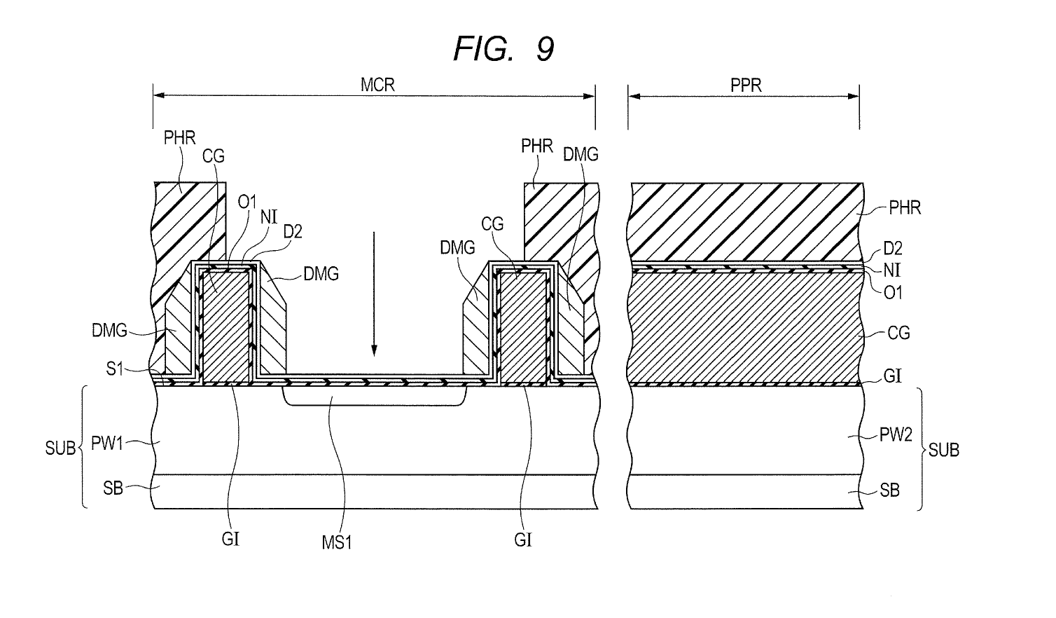

With reference to FIG. 9, using the dummy gate electrodes DMG as a mask, the impurity region MS1 as the first source region is formed in a part of the main surface S1 of the semiconductor substrate SUB in accordance with a self-alignment technique using a typical ion implantation technique. Specifically, using a typical photoengraving technique, the photoresist PHR is formed into a pattern so as to expose the region where the source region is to be formed. Then, into the main surface of the semiconductor substrate SUB not covered with the pattern of the photoresist PHR, an n-type impurity is ion-implanted to form the lower-concentration source region MS1 as the first source region.

The n-type impurity in the lower-concentration source region MS1 formed herein preferably has a concentration approximately equal to that of the n-type impurity implanted to form the impurity region MV. The lower-concentration source region MS1 also preferably has a junction depth approximately equal to that of the impurity region MV.

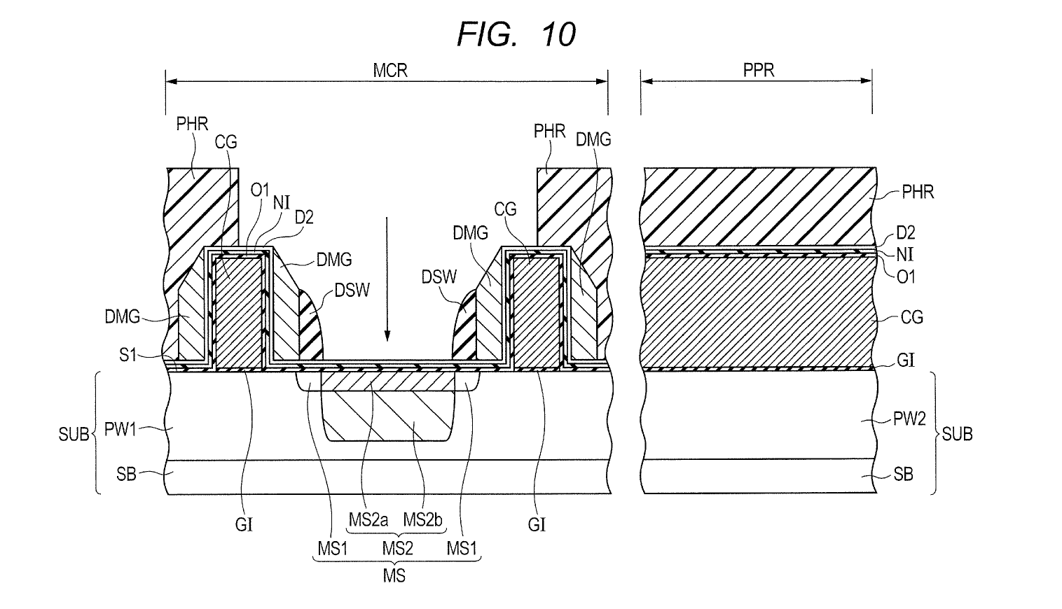

Referring to FIG. 10, the photoresist PHR is temporarily removed by ashing or the like. In that state, a silicon nitride film or a laminate structure including a silicon oxide film and a silicon nitride film is formed and etched back by typical anisotropic dry etching. As a result, in the memory cell region MCR, dummy sidewall insulating films DSW are formed so as to be adjacent to the dummy gate electrodes DMG on the side where the source region is to be formed eventually. The dummy sidewall insulating films DSW may also be formed so as to be adjacent to (come in contact with the side surfaces of) the dummy gate electrodes DMG on the side where the drain regions are formed.

Using the dummy-source-side sidewall insulating films DSW which are the dummy sidewall insulating films on the side where the source region MS is to be formed eventually as a mask, an n-type impurity is ion-implanted again. Note that, at this time, at the same position as in the step of FIG. 9, the photoresist PHR has been formed again into a pattern and, in accordance with a self-alignment technique using the dummy-source-side sidewall insulating films DSW (on the side where the source region MS is formed), the higher-concentration source region MS2 as the second source region is formed. In other words, using the dummy-source-side sidewall insulating films DSW as a mask, in parts of the main surface S1 of the semiconductor substrate SUB, the impurity regions MS2a and MS2b each as the source region are formed in parts of the main surface S1 of the semiconductor substrate SUB in accordance with a self-alignment technique using a typical ion implantation technique.

Specifically, the photoresist PHR is formed into a pattern using a typical photoengraving technique so as to expose the region where the source region is to be formed. Then, into the main surface of the semiconductor substrate SUB not covered with the pattern of the photoresist PHR, an n-type impurity is ion-implanted to form the higher-concentration source region MS2.

The n-type impurity ion-implanted herein has an impurity concentration higher than that of the n-type impurity ion-implanted to form the lower-concentration source region MS1 mentioned above and a junction depth deeper than that thereof. Accordingly, in the upper region (close to the main surface S1) of the higher-concentration source region MS2, the upper source region MS2a is formed in the main surface S1 such that the higher-concentration source region MS2 overlaps the lower-concentration source region MS1 and the lower source region MS2b is formed so as to come in contact with the lower surface of the upper source region MS2a. Thus, the higher-concentration source region MS2 which is a combination of the source regions MS2a and MS2b is formed.

When viewed in the vertical direction, the lower source region MS2b as the first source region and the upper source region MS2a as the second source region in contact with the upper surface thereof are each formed using the dummy-source-side sidewall insulating films DSW as a mask. The upper source region MS2a as the second source region has an n-type impurity concentration higher than that of the lower source region MS2b as the first source region since the n-type impurity concentration of the originally existing lower-concentration source region MS1 is added to the concentration of the n-type impurity implanted in the step of FIG. 10. When viewed in the vertical direction, the impurity region MS1 formed using the dummy gate electrodes DMG as a mask in the step of FIG. 9 is formed as third source regions MS1 different from each of the foregoing first and second source regions MS2b and MS2a.

When viewed in the lateral direction, the regions (regions close to the dummy gate electrodes DMG) in the both end portions of the lower-concentration source region MS1 in which the impurity is not additionally implanted in the step of FIG. 10 are eventually formed as the lower-concentration source regions MS1 each as the first source region. Into the middle portion of the lower-concentration source region MS1, the impurity is additionally implanted in the step of FIG. 10 to form the higher-concentration source region MS2 as the second source region. The lower-concentration source regions MS1 are formed in the main surface S1 using the dummy gate electrodes DMG as a mask. The higher-concentration source region MS2 is formed in the main surface S1 using the dummy-source-side sidewall insulating films DSW as a mask.

Thus, the source region MS is formed which includes the lower-concentration source regions MS1 and the higher-concentration source region MS2 (including the upper source region MS2a and the lower source region MS2b).

Note that the lower-concentration source regions MS1 formed using the dummy gate electrodes DMG as a mask form only a part of the source region. In forming the higher-concentration source region MS2 as the other region forming the source region, the dummy gate electrodes DMG need not necessarily be used. However, it is considered here that, as long as at least a part of the source region, such as the foregoing regions MS1, is formed using the dummy gate electrodes DMG as a mask, requirements on the configuration (source region is formed using the dummy gate electrodes DMG as a mask) in the embodiment are met.

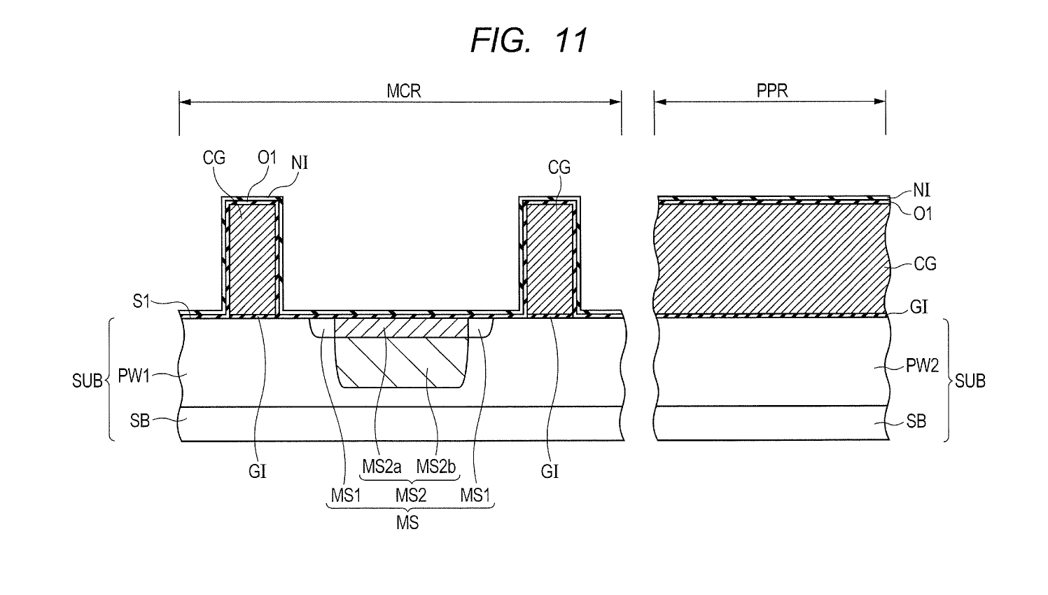

Referring to FIG. 11, after the photoresist PHR is removed by ashing or the like, the dummy sidewall insulating films DSW and the dummy gate electrodes DMG are removed by etching. Also, in each of the memory cell region MCR and the peripheral circuit region PPR, using the second insulating film NI including the silicon nitride film as an etching stopper, the dummy insulating film D2 is removed by etching.

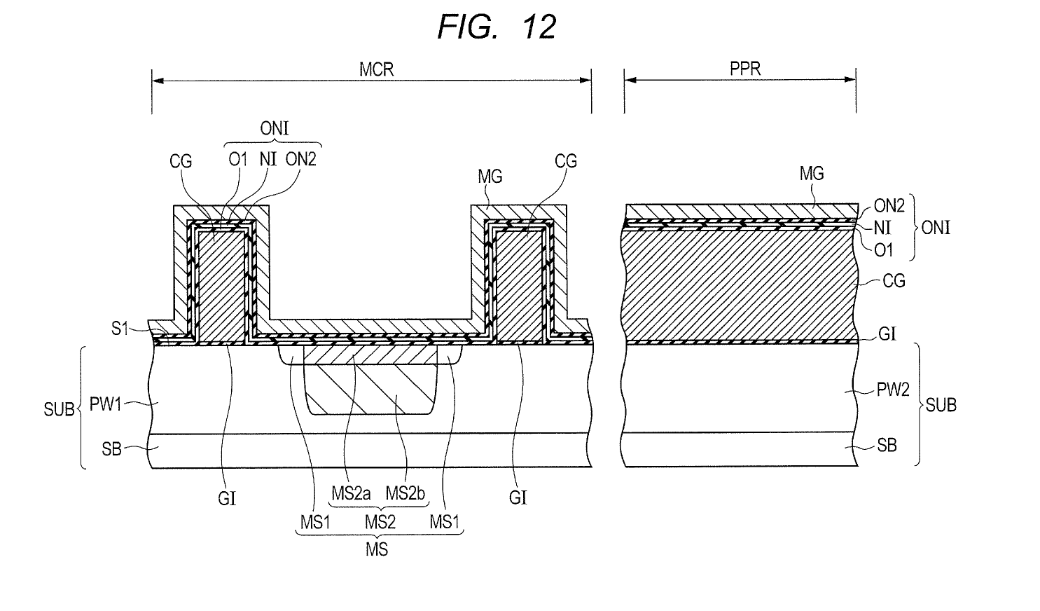

Referring to FIG. 12, in each of the memory cell region MCR and the peripheral circuit region PPR, the third insulating film ON2 is formed so as to cover the upper surface of the second insulating film NI1 in the uppermost layer in the laminated insulating films covering the upper surfaces and the side surfaces of the control gate electrodes CG in each of the memory cell region MCR and the peripheral circuit region PPR.

The third insulating film ON2 includes the silicon oxide film and is formed by, e.g., a typical CVD method. However, the third insulating film ON2 is more preferably formed as a silicon oxynitride film containing nitrogen. The third insulating film ON2 is preferably formed by so-called ISSG (In Situ Steam Generation) oxidation to have a thickness of, e.g., not less than 4 nm and not more than 7 nm. Thus, the laminate structure ONI intended to serve as the memory gate insulating film is formed which has a configuration in which the first insulating film O1, the second insulating film NI, and the third insulating film ON2 are stacked.

Referring again to FIG. 12, in each of the memory cell region MCR and the peripheral circuit region PPR, the thin film MG of polysilicon which is a semiconductor film intended to serve as the memory gate electrodes MG is formed so as to cover the entire upper surface of the third insulating film ON2 in the uppermost layer in the insulating films laminated so as to cover the upper surfaces and side surfaces of the control gate electrodes CG. The thin film of polysilicon is formed by a typical CVD method so as to have a thickness of not less than 30 nm and not more than 100 nm. However, as the thin film MG, instead of polysilicon, non-crystalline (amorphous) silicon may also be deposited.

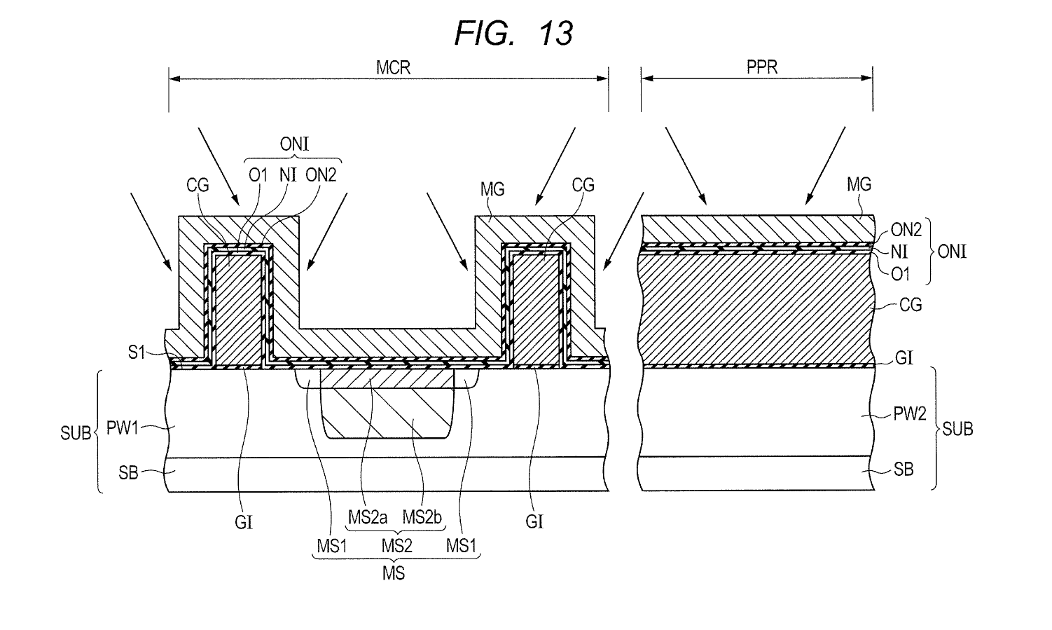

Referring to FIG. 13, into the foregoing thin film MG, a second-conductivity-type, i.e., p-type impurity (e.g., boron or indium) is implanted using a typical ion implantation technique. However, in the same manner as when the first-conductivity-type (n-type) impurity is introduced into the thin film of each of the control gate electrodes CG described above, by also, e.g., causing a gas for deposition to include a doping gas (gas for adding a p-type impurity) here during the deposition in FIG. 12 instead of using an ion implantation technique, the thin film of polysilicon containing the p-type impurity may also be formed. That is, here, when the thin film MG of polysilicon which is a semiconductor film intended to serve as the memory gate electrodes MG is formed using an ion implantation technique or a method other than the ion implantation technique, the second-conductivity-type (p-type) impurity can be introduced into the thin film.

In the case of using an ion implantation technique when the foregoing p-type impurity is introduced, a conductive impurity is implanted in a direction shown by the arrow in FIG. 13, i.e., in a direction oblique to a direction parallel or perpendicular to a direction in which the main surface S1 of the semiconductor substrate SUB extends. This allows the p-type impurity to be implanted even into, e.g., the surfaces of the thin film MG formed over the side surfaces of the control gate electrodes CG.

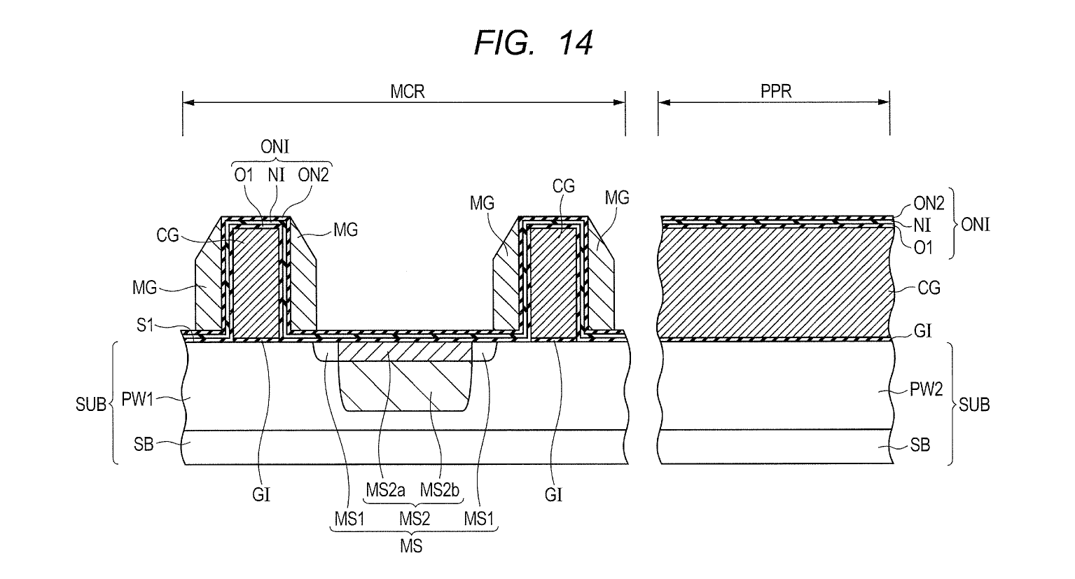

Referring to FIG. 14, anisotropic dry etching is performed using the third insulating film ON2 in the uppermost layer (layer most distant from the semiconductor substrate SUB) forming the laminated insulating films as an etching stopper to etch back the thin film MG. As a result, in the memory cell region MCR, over the main surface S1 of the semiconductor substrate SUB, the memory gate electrodes MG are formed so as to be adjacent to the control gate electrodes CG (come in contact with the third insulating films ON2 over the side surfaces of the control gate electrodes CG). The memory gate electrodes MG are each formed to have a thickness in the vertical direction in the drawing which decreases with distance from the control gate electrodes CG (outwardly from the control gate electrodes CG). On the other hand, the thin film MG in the peripheral circuit region PPR is etched away.

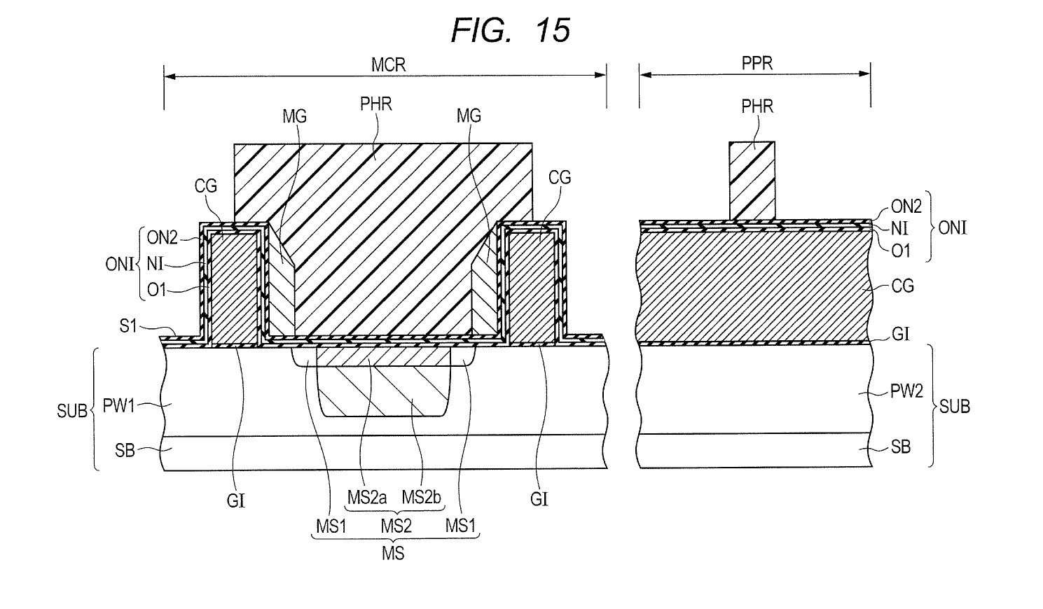

Referring to FIG. 15, in the memory cell region MCR, the photoresist PHR is formed into a pattern using a typical photoengraving technique so as to cover the source regions MS1 and the memory gate electrodes (and a part of each of the control gate electrodes CG) on the side where the source region MS is located. In the peripheral circuit region PPR, the photoresist PHR is formed into a pattern so as to cover the thin film CG in the region where the gate electrode is to be formed from immediately above.

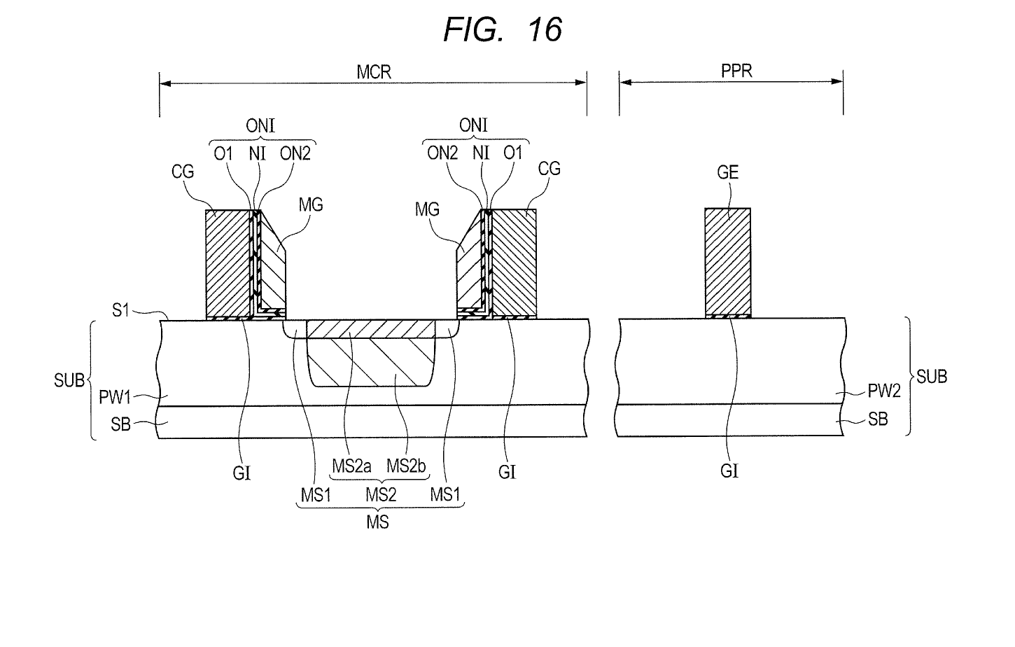

Referring to FIG. 16, in the memory cell region MCR, by typical etching using the pattern of the photoresist PHR, the memory gate electrodes MG and the laminated insulating films ONI are removed from the region not covered with the photoresist PHR. By the removal of the photoresist PHR by ashing or the like, the memory gate electrodes MG remain on the side of the control gate electrodes CG where the source region MS is located. The laminated insulating films ONI are formed as the memory gate insulating films ONI extending from the regions interposed between the remaining memory gate electrodes MG and the semiconductor substrate SUB located immediately thereunder in continuous relation to the regions interposed between the control gate electrodes CG and the memory gate electrodes MG. That is, the memory gate insulating films ONI extending in the direction along the main surface of the semiconductor substrate SUB are bent about 90° from the direction at the lowermost portions (lower portions close to the semiconductor substrate SUB) of the control gate electrodes CG to extend in directions along the side surfaces of the control gate electrodes CG.

In the peripheral circuit region PPR, by typical etching using the pattern of the photoresist PHR, the thin film CG is formed as the gate electrode GE and the insulating film GI located immediately thereunder is formed as the gate insulating film GI. The thin film CG and the insulating film GI in the region other than that described above are entirely removed and the insulating film ONI over the thin film CG is also removed.

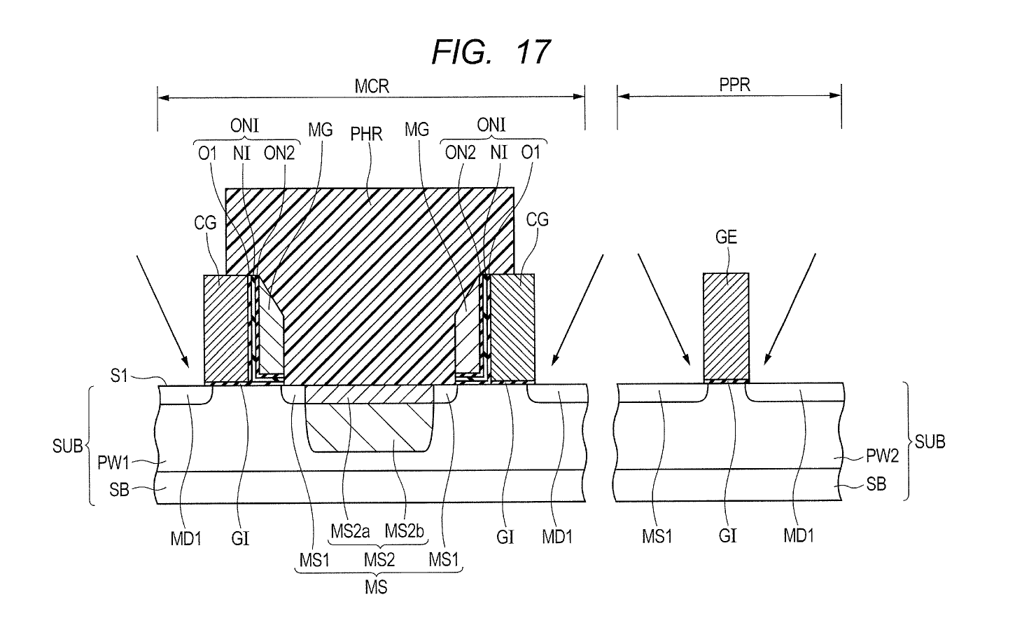

Referring to FIG. 17, in the memory cell region MCR, the photoresist PHR is formed into a pattern using a typical photographic engraving technique at the same position as in the step of FIG. 15, i.e., so as to cover the source region MS1 and the memory gate electrodes MG (and a part of each of the control gate electrodes CG). Then, in this state, an n-type impurity is implanted into portions of the main surface S1 of the semiconductor substrate SUB which are located on the side of the control gate electrodes CG and the memory gate electrodes MG opposite to the side thereof where the source region MS is located (externally of the control gate electrodes CG) using a typical ion implantation technique. The regions into which the n-type impurity is implanted are substantially the same region as the impurity region MV formed by the step of FIG. 5.

In the process, in accordance with a self-alignment technique using the control gate electrodes CG as a mask, the impurity region MV becomes the drain regions MD formed in the main surface S1. Note that the ion implantation performed herein may also be performed in a direction oblique to the main surface S1 of the semiconductor substrate SUB.

Note that, in the peripheral circuit region PPR, an n-type impurity is implanted into the main surface S1 of the semiconductor substrate SUB on both sides of the gate electrode GE using a typical ion implantation technique. By the self-alignment technique using the gate electrode GE as a mask, the source region MS1 and the drain region MD1 are formed at the positions shown in the drawing.

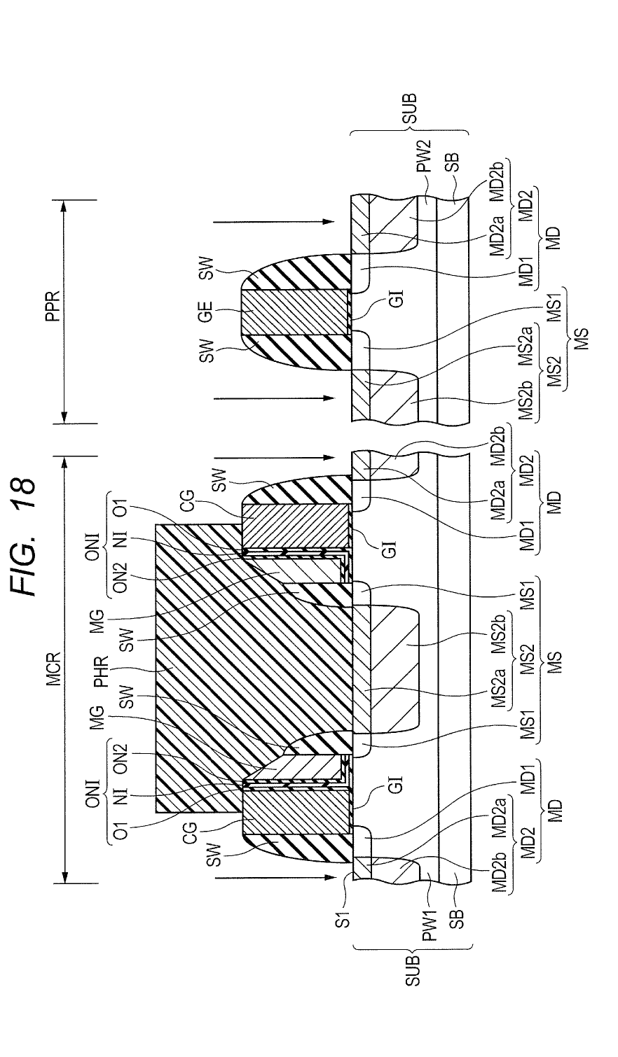

Referring to FIG. 18, the photoresist PHR in the step of FIG. 17 is removed by ashing or the like. In that state, a silicon nitride film or a laminate structure including a silicon oxide film and a silicon nitride film is formed and etched back by typical anisotropic dry etching. As a result, in the memory cell region MCR, the sidewall insulating films SW are formed so as to be adjacent to the control gate electrodes CG and the memory gate electrodes MG (so as to come in contact with the side surfaces).

The sidewall insulating films SW have shapes which are thinner with distance from the electrodes CG and MG. Here, for the sake of convenience, the sidewall insulating films SW formed so as to be adjacent to the control gate electrodes CG (on the side where the drain regions MD are to be formed eventually) are referred to as the drain-side sidewall insulating films and the sidewall insulating films SW formed to be adjacent to the memory gate electrodes MG (on the side where the source region MS is located) are referred to as the source-side sidewall insulating films.

Next, in the memory cell region MCR, the photoresist PHR is formed into a pattern again at the same position as in the step of FIG. 17, i.e., so as to cover the source region MS1 and the memory gate electrodes MG (and a part of each of the control gate electrodes CG) using a typical photoengraving technique. Then, in this state, an n-type impurity is implanted into the portions of the main surface S1 of the semiconductor substrate SUB which are located on the side of the control gate electrodes CG and the memory gate electrodes MG opposite to the side thereof where the source region MS (externally of the control gate electrodes CG) is located using a typical ion implantation technique.

At this time, in accordance with a self-alignment technique using the drain-side sidewall insulating films SW as a mask, the impurity is additionally implanted into the region of the main surface S1 located externally of the drain regions MD formed in the step of FIG. 17 when viewed from the drain-side sidewall insulating films SW, i.e., into the middle portion of the impurity region MV.

Note that, here, an n-type impurity is implanted so as to form an impurity region having an impurity concentration higher than that of the impurity region formed in the step of FIG. 17 and a junction depth deeper than that thereof. As a result, the regions subjected to the ion implantation in the step of FIG. 18 are formed as the higher-concentration drain regions MD2 each as the second drain region. On the other hand, the regions on the both end sides (regions close to the control gate electrodes CG) of the higher-concentration drain regions MD2 which substantially overlap the impurity region MV and into which an n-type impurity has been implanted only by the step of FIG. 17 are formed as the lower-concentration drain regions MD1 each as the first drain region.

That is, when viewed in a lateral direction, the regions in the both end portions (regions close to the control gate electrodes CG) of the impurity region MV into which the impurity is not additionally implanted in the step of FIG. 18 are formed as the lower-concentration drain regions MD1 each as the first drain region. On the other hand, into the middle portions of the impurity region MV, the impurity is additionally implanted in the step of FIG. 18 to form the higher-concentration drain regions MD2 each as the second drain region having the n-type impurity concentration higher than that of the first drain region. The lower-concentration drain regions MD1 are formed in the main surface S1 using the control gate electrodes CG as a mask. The higher-concentration drain regions MD2 are formed in the main surface S1 using the drain-side sidewall insulating films SW as a mask.

When viewed in a longitudinal direction, in the step of FIG. 18, the upper drain regions MD2a (second drain region) are formed in the main surface S1 using the drain-side sidewall insulating films SW as a mask such that the higher-concentration drain regions MD2 overlap the impurity region MV. Likewise, using the drain-side sidewall insulating films SW as a mask, the lower drain regions MD2b (first drain region) are formed so as to come in contact with the lower surfaces of the upper drain regions MD2a. Thus, the higher-concentration drain regions MD2 each as a combination of the drain regions MD2a and MD2b are formed.

Each of the upper drain regions MD2a as the second drain region has an n-type impurity concentration higher than that of each of the lower drain regions MD2b as the first drain region since the n-type impurity concentration of the originally existing impurity region MV is added to the concentration of the n-type impurity implanted in the step of FIG. 18.

Thus, the drain regions MD are formed which include the lower-concentration drain regions MD1 and the higher-concentration drain regions MD2 (including the upper drain regions MD2a and the lower drain regions MD2b).

In the peripheral circuit region PPR, in the same manner as in the memory cell region MCR, the higher-concentration source region MS2 and the higher-concentration drain region MD2 are formed in accordance with a self-alignment technique using a typical ion implantation technique using the sidewall insulating films SW formed so as to cover the side surfaces of the gate electrode GE as a mask. Of the higher-concentration source region MS2 and the higher-concentration drain region MD2, the regions overlapping the source region MS1 and the drain region MD1 each formed in the step of FIG. 17 serve as the upper source region MS2a and the upper drain region MD2a and the other regions serve as the lower source region MS2b and the lower drain region MD2b. On the other hand, the regions which are located on the both end sides of the higher-concentration source region MS2 and the higher-concentration drain region MD2 and into which the impurity has been implanted only by the step of FIG. 17 are formed as the lower-concentration source region MS1 and the lower-concentration drain region MD1.

After the foregoing individual steps, the pattern of the photoresist PHR is removed by ashing or the like and generally known post-processing such as the formation of interlayer insulating films is performed, whereby the semiconductor device having the MONOS flash memory is formed.

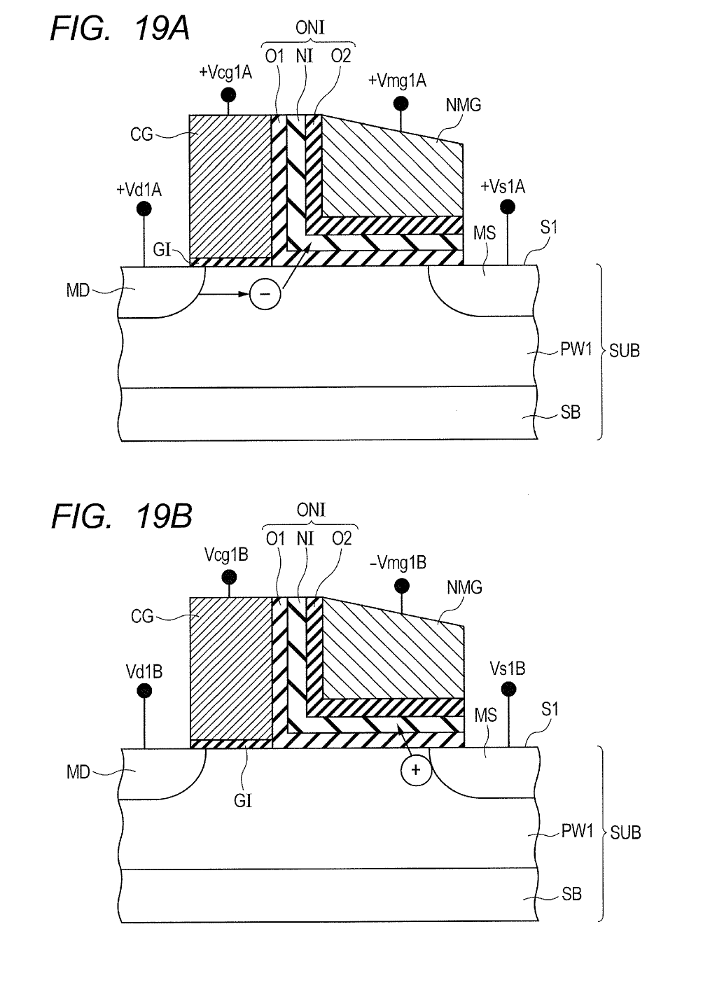

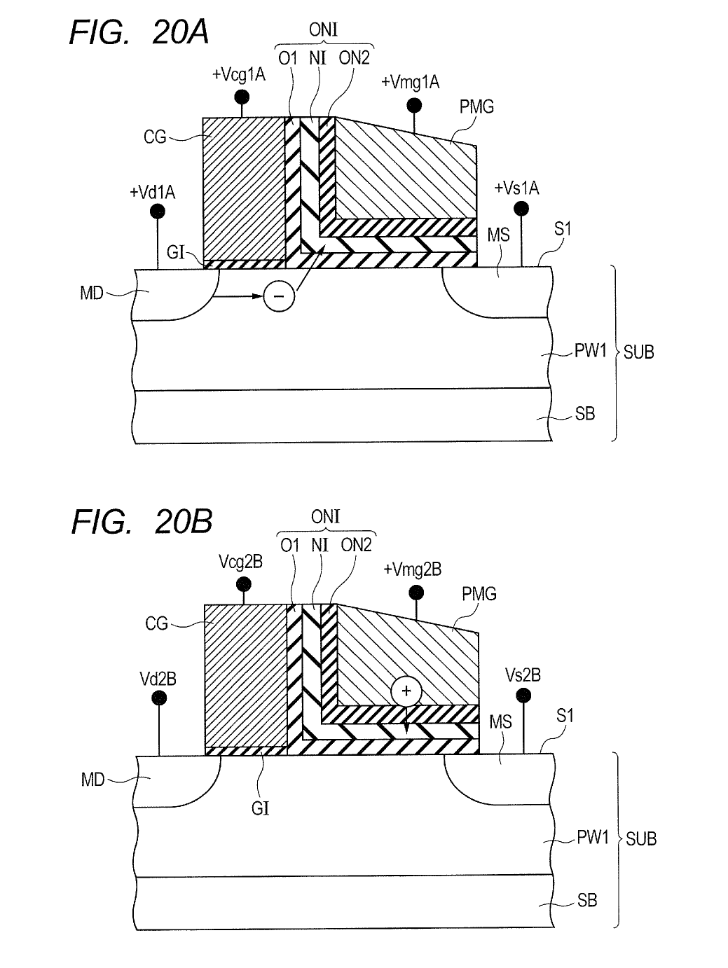

Next, a description will be given of the function/effect of the embodiment. First, referring to the configuration of a comparative example of FIGS. 19A and 19B and the configuration of the embodiment of FIGS. 20A and 20B, a description will be given of a write operation and an erase operation to each of the MONOS flash memories.

Referring to FIG. 19A, the MONOS flash memory of the comparative example includes the control gate electrode CG containing an n-type impurity, and an n-type memory gate electrode NMG containing an n-type impurity. The memory gate insulating film ONI has a structure in which the first insulating film O1 including a silicon oxide film, the second insulating film NI including a silicon nitride film, and a third insulating film O2 including a silicon oxide film (not containing nitrogen) are stacked in this order. The source region MS and the drain region MD contain an n-type impurity in the same manner as in the embodiment.

During a data write operation to the MONOS flash memory of the comparative example, a voltage +Vcg1A is applied to the control gate electrode CG, a voltage +Vmg1A is applied to the n-type memory gate electrode NMG, a voltage +Vd1A is applied to the drain region MD, and a voltage +Vs1A is applied to the source region MS. Each of the voltages has a positive value and +Vs1A is higher than +Vd1A.

At this time, the electron supplied from the drain region MD into the semiconductor substrate SUB (shown by the encircled “−”) passes through the first insulating film O1 immediately under the n-type memory gate electrode NMG from the semiconductor substrate SUB side to be injected into the second insulating film NI. The electron injected into the second insulating film NI is trapped by a trap level in the second insulating film NI. As a result, the threshold voltage of the storage transistor increases.

Referring to FIG. 19B, from the MONOS flash memory of the comparative example, data is erased in accordance with a BTBT (Band-To-band Tunneling) hot-hole-injection erase method. Specifically, a voltage Vcg1B is applied to the control gate electrode CG, a voltage −Vmg1B is applied to the n-type memory gate electrode NMG, a voltage Vd1B is applied to the drain region MD, and a voltage Vs1B is applied to the source region. Here it is assumed that, normally, each of the voltages Vcg1B and Vd1B is 0 V, the voltage −Vmg1B has a negative value, and the voltage Vs1B has a positive value. At this time, the hole (shown by the encircled “+”) resulting from a BTBT (band-to-band tunneling phenomenon) is supplied from the source region MS into the semiconductor substrate SUB and further passes through the first insulating film O1 immediately under the n-type memory gate electrode NMG from the semiconductor substrate SUB to be injected into the second insulating film NI. As a result, the threshold voltage of the storage transistor decreases.

Thus, in such an n-type MONOS flash memory including the n-type memory gate electrode NMG as that of the comparative example, during each of a data write operation and a data erase operation, an electron or a hole passes through the first insulating film O1 under the memory gate electrode NMG. As a result, when the number of times a rewrite operation is performed increases, the degradation of the first insulating film O1 may become obvious to possibly affect a rewrite property and reliability (the function of the second insulating film NI to hold charges).

Also in the n-type MONOS flash memory of the comparative example, when data is to be written, a positive voltage is applied to the n-type memory gate electrode NMG while, when data is to be erased, a negative voltage is applied to the n-type memory gate electrode NMG. Accordingly, two types of power supply circuits are needed as peripheral circuits to increase the area occupied by the power supply circuits in the entire semiconductor device. This causes the need to accordingly reduce the area occupied by a flash module including the flash memory and the like or reduce the area occupied by the elements forming other peripheral circuits.

Referring to FIG. 20A, the MONOS flash memory of the embodiment is different from the MONOS flash memory of the comparative example of FIGS. 19A and 19B in that the memory gate electrode is a p-type memory gate electrode PMG containing a p-type impurity.

When data is written to the MONOS flash memory of the embodiment, in the same manner as in the MONOS flash memory of the comparative example, the voltage +Vcg1A is applied to the control gate electrode CG, the voltage +Vmg1A is applied to the p-type memory gate electrode PMG, the voltage +Vd1A is applied to the drain region MD, and the voltage +Vs1A is applied to the source region MS. These values are the same as the individual values shown in FIG. 19A. In this manner, in the same manner as in the foregoing comparative example, the electron passes through the first insulating film O1 to be injected into the second insulating film NI1.

Referring to FIG. 20B, when data is erased from the MONOS flash memory of the embodiment, a voltage Vcg2B is applied to the control gate electrode CG, a voltage +Vmg2B is applied to the p-type memory gate electrode PMG, a voltage Vd2B is applied to the drain region MD, and a voltage Vs2B is applied to the source region. Here it is assumed that, normally, each of the voltages Vcg2B, Bd2B, and Vs2B is 0 V and the voltage +Vmg2B has a positive value and is higher than the voltage +Vmg1A during a data write operation.

At this time, the hole generated from the p-type memory gate electrode MG passes through the third insulating film immediately thereunder to be injected into the second insulating film NI. Thus, during a data erase operation, each of the electron and the hole is injected into the second insulating film NI without passing through the first insulating film O1. Accordingly, in the embodiment, it is possible to reduce the number of times the electron or hole passes through the first insulating film O1 compared to that in the foregoing comparative example and suppress the degradation of the first insulating film O1. This can improve the rewrite property (the number of times a rewrite operation can be performed) and reliability.

Also, in the embodiment, during each of a data write operation and a data erase operation, a positive voltage (+Vmg1A or +Vmg2B) is applied to the p-type memory gate electrode PMG. Accordingly, it is possible to eliminate a power supply circuit for applying a negative voltage from the peripheral circuits and save a space in the semiconductor device such as the area occupied by each of the elements.

As shown next in FIGS. 20A and 20B, the memory gate insulating film ONI in the embodiment is preferably formed as the silicon oxynitride film ON2 in which the third insulating film in the uppermost layer contains nitrogen. This allows easier injection of the hole from the p-type memory gate electrode PMG into the third insulating film ON2 than in the case where the third insulating film is formed as the silicon oxide film O2 not containing nitrogen as in, e.g., FIGS. 19A and 19B.

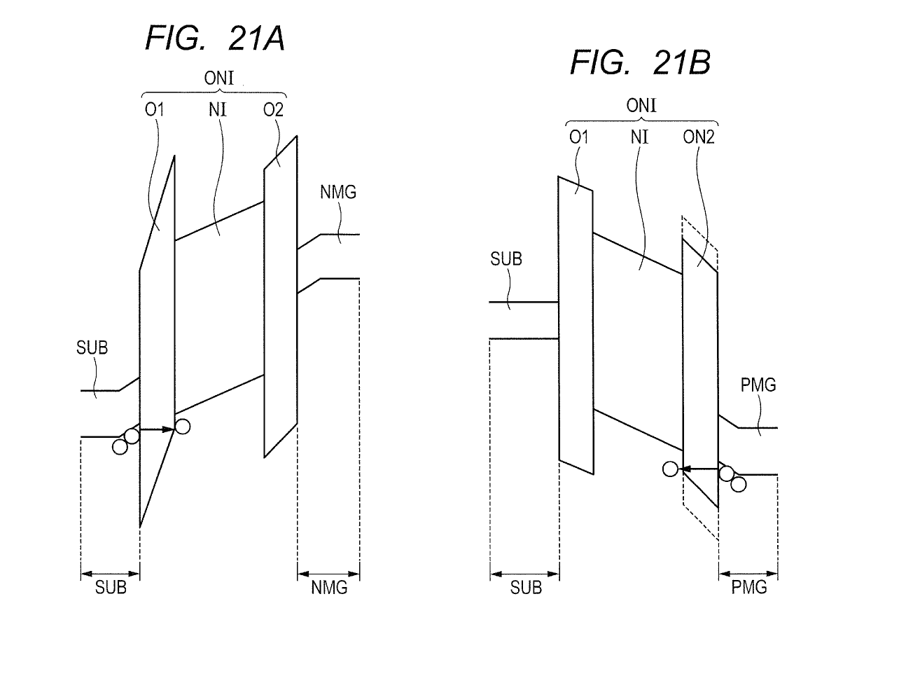

Referring to FIG. 21A, when the n-type memory gate electrode NMG is used, the hole (the circle in the drawing) can be supplied into the second insulating film NI only from the semiconductor substrate SUB (as shown by the arrow in the drawing). On the other hand, as shown in FIG. 21B, when the p-type memory gate electrode PMG is used, by applying a positive voltage to the p-type memory gate electrode MG, the hole can be supplied into the second insulating film NI from the p-type memory gate electrode PMG through the third insulating film.

Referring to FIG. 21B, by causing the third insulating film ON2 to contain nitrogen, the potential barrier of the third insulating film against the hole is reduced to be lower than the potential barrier (shown by the dotted line in FIG. 21B) of the third insulating film against the hole when nitrogen is not contained in the third insulating film. This allows the hole to easily pass through the third insulating film ON2 containing nitrogen.

The third insulating film ON2 as the silicon oxynitride film mentioned above is formed by so-called ISSG oxidation which is a type of a CVD method. The third insulating film ON2 thus formed has insulation performance inferior to that of a silicon oxide film (not containing nitrogen) formed by, e.g., a thermal oxidation method, but can be formed at lower cost than that of the thermal oxide film. Unlike, e.g., the third insulating film O2 in the comparative example, the third insulating film ON2 in the embodiment is not required to have a high insulating property comparable to that of the third insulating film O2 in the comparative example since the hole passes therethrough. Therefore, by forming the silicon oxynitride film containing nitrogen by the foregoing method, it is possible to form a memory gate insulating film which satisfies an operational need at low cost.

Also in the embodiment, the source region includes the lower-concentration source regions MS1 each as the first source region and the higher-concentration source region MS2 as the second source region having an n-type impurity concentration higher than that of each of the lower-concentration source regions MS1. Accordingly, compared to the case where only the lower-concentration source region MS1 is provided as the source region, the electric resistance of the whole source region can be reduced and, consequently, the source-drain electric resistance can also be reduced. In addition, since the higher-concentration source region MS2 is formed in a region located between the source region and the drain region and relatively close to the main surface S1 through which an electron or the like laterally passes, the electron or the like is allowed to more easily pass therethrough. Thus, the drive capability of the MONOS flash memory can be enhanced.

The lower-concentration source regions MS1 each as the first source region are located immediately under the source-side sidewall insulating films SW and the higher-concentration source region MS2 as the second source region is located externally of the source-side sidewall insulating films SW. Accordingly, the source region MS is formed such that, in the lateral direction along the main surface of the semiconductor substrate SUB, the impurity concentration is higher and the electric resistance is lower in the middle portion of the source region MS than in the both end portions thereof. This allows the effect of reducing the electric field in the source region to be obtained. In addition, the electric resistance in such a region as the source region and a region between the source region and the drain region can be reduced to allow the drive capability of the MONOS flash memory to be enhanced.

In the method of manufacturing the semiconductor device of the present embodiment, after the source region MS is formed using the dummy gate electrodes DMG and the dummy gate electrodes DMG are removed, the authentic memory gate electrodes MG are formed and the drain regions MD are formed in a state where the memory gate electrodes MG are covered. As a result, it is possible to form the source region MS having a high impurity concentration without impairing the high p-type impurity concentration of each of the memory gate electrodes MG.

In the present embodiment, after the lower-concentration source regions MS1 each as the first source region is formed using the dummy gate electrodes DMG as a mask, the dummy-source-side sidewall insulating films DSW are formed on the side of the dummy gate electrodes DMG where the source region is located so as to be adjacent to the dummy gate electrodes DMG. Then, using the dummy-source-side sidewall insulating films DSW as a mask, the higher-concentration source region MS2 as the second source region is formed. Accordingly, the source region MS is formed such that, in the lateral direction along the main surface of the semiconductor substrate SUB, the impurity concentration is higher and the electric resistance is lower in the middle portion of the source region MS than in the both end portions thereof. This allows the effect of reducing the electric field in the source region to be obtained.

Note that, in the foregoing description, when the higher-concentration source region MS2 having a lateral width smaller than that of each of the lower-concentration source regions MS1 is formed, the dummy-source-side sidewall insulating films DSW are formed as a mask for a self-alignment technique. However, if ion implantation is performed obliquely to implant ions into desired regions as in the step of, e.g., FIG. 13, the higher-concentration source region MS2 occupying the same region as that occupied by the higher-concentration source region MS2 formed by the step of FIG. 10 can be formed without necessarily forming the dummy-side sidewall insulating films DSW as a mask.

Also in the embodiment, each of the drain regions includes the lower-concentration drain region MD1 as the first drain region and the higher-concentration drain region MD2 as the second drain region having an n-type impurity concentration higher than that of the lower-concentration drain region MD1. Accordingly, compared to the case where only the lower-concentration drain region MD1 is provided as the drain region, the electric resistance of the whole drain region can be reduced and, consequently, the source-drain electric resistance can also be reduced. In addition, since the higher-concentration drain region MD2 is formed in the region located between the source region and the drain region and relatively close to the main surface S1 through which an electron or the like laterally passes, the electron or the like is allowed to more easily pass therethrough. Thus, the drive capability of the MONOS flash memory can be enhanced.

The lower-concentration drain region MD1 as the first drain region is located immediately under the drain-side sidewall insulating film SW and the higher-concentration drain region MD2 as the second drain region is located externally of the drain-side sidewall insulating film SW. Accordingly, the drain region MD is formed such that, in the lateral direction along the main surface of the semiconductor substrate SUB, the impurity concentration is higher and the electric resistance is lower in the middle portion of the drain region MD than in the both end portions thereof. This allows the effect of reducing the electric field in the drain region to be obtained.

In a vertical direction crossing the main surface of the semiconductor substrate SUB also, the source region MS includes the lower source region MS2b as the first source region and the upper source region MS2a as the second source region which is in contact with the upper surface of the lower source region MS2b and has an n-type impurity concentration higher than that of the lower source region MS2b. Each of the drain regions MD also includes the lower drain region MD2b as the first drain region and the upper drain region MD2b as the second drain region which is in contact with the upper surface of the lower drain region MD2b and has an n-type impurity concentration higher than that of the lower drain region MD2b. Therefore, in the vertical direction also, the impurity concentration can be increased to allow a reduction in the electric resistance of the whole source region and allow an increase in the drive capability of the MONOS flash memory.

The lower source region MS2b and the upper source region MS2a as the first source region and the second source region in the vertical direction are formed using the dummy-source-side sidewall insulating films DSW as a mask. On the other hand, the lower-concentration source regions MS1 each as the third source region are formed using the dummy gate electrodes DMG as a mask. Therefore, in the vertical direction also, the impurity concentration can be increased to allow a reduction in the electric resistance of the entire source region and allow an increase in the drive capability of the MONOS flash memory.

It is difficult to form the source region including the two impurity regions having different concentrations described above after, e.g., the memory gate electrodes MG each having a p-type impurity are formed. A description will be given below thereof.

For example, when the source region on the side where the memory gate electrodes MG are located is formed after the formation of the p-type memory gates MG such that the source region has a concentration gradient, a higher-concentration n-type impurity region for the source region is introduced using a typical ion implantation technique. At this time, if ion implantation is performed without forming the photoresist PHR or the like and covering the p-type memory gate electrodes MG therewith, an n-type impurity is implanted in a large amount in each of the p-type memory gate electrodes MG to result in the problem of a reduction in the p-type impurity concentration of the memory gate electrode MG. Moreover, since the memory gate electrode MG is extremely thin, the impurity may be unintentionally implanted to pass through the memory gate electrodes MG during the ion implantation and reach the interior of the semiconductor substrate SUB.

However, when the n-type impurity for the source region is implanted into the regions adjacent to (located externally of) the memory gate electrodes MG, even though it is attempted to form the photoresist PHR into a pattern so as to cover the memory gate electrodes MG therewith, it is difficult to form the photoresist PHR into a pattern such that the end portions thereof substantially coincide with the end portions of the memory gate electrodes MG. This is because the uppermost surface of each of the memory gate electrodes MG is inclined such that the thickness thereof is smaller in the outer portion thereof than in the inner portion thereof.

Accordingly, when the photoresist PHR is formed into a pattern covering the upper surfaces of the memory gate electrodes MG, the photoresist PHR needs to be formed into the pattern such that the end portions thereof are located at positions laterally away from the outer end portions of the memory gate electrodes MG (the end portions thereof are not located immediately over the memory gate electrodes MG). In this case, it is difficult to form an impurity region by implantation at a position externally adjacent to each of the memory gate electrodes MG using such a pattern of the photoresist PHR.

For each of the reasons given above, in the embodiment, the dummy gate electrodes DMG are formed first each as a dummy memory gate electrode and, in accordance with a self-alignment technique using the dummy gate electrodes DMG, the source region MS (e.g., the source region MS2 as at least a part thereof) is formed. After the formation of the source region MS, the dummy gate electrodes DMG are removed and the memory gate electrodes MG are formed. In a state where the memory gate electrodes MG (also the region where the source region MS is formed) are covered with the pattern of the photoresist PHR, the drain region MD is formed.

Consequently, when the source region MS is formed, the dummy gate electrodes DMG are used and the memory gate electrodes have not been formed yet. Therefore, it is possible to form the higher-concentration source region MS without being concerned about the implantation of an n-type impurity into the p-type memory gate electrodes. When the drain regions MD are formed, the memory gate electrodes MG are formed. However, processing is performed in a state where the memory gate electrodes MG are covered with the pattern of the photoresist PHR (such that the source region MS is included therein, i.e., the end portions of the photoresist PHR do not coincide with the end portions of the memory gate electrodes MG). This can reduce the possibility of impurity implantation into the memory gate electrodes MG.

The manufacturing method in which the source region MS is formed using the dummy gate electrodes DMG (before the formation of the memory gate electrodes MG) is useful as a method for forming the MONOS flash memory of the embodiment.

In the description given above, the memory gate electrodes MG are each formed as a thin film (semiconductor layer) of polysilicon containing a p-type impurity, but the memory gate electrodes MG are not limited thereto. The same effect can be achieved with a flash memory having the memory gate electrodes MG each formed as a thin film of polysilicon containing an n-type impurity or as a thin film of polysilicon containing neither an n-type impurity nor a p-type impurity.

While the invention achieved by the present inventors has been specifically described heretofore based on the embodiments thereof, the present invention is not limited to the foregoing embodiments. It will be appreciated that various changes and modifications can be made in the invention within the scope not departing from the gist thereof.

What is claimed is:

1. A semiconductor device, comprising:
a semiconductor substrate having a main surface;
a first gate electrode formed over the main surface;
a second gate electrode formed so as to be adjacent to the first gate electrode over the main surface;
an insulating film extending from a region interposed between the second gate electrode and the semiconductor substrate in continuous relation to a region interposed between the first gate electrode and the second gate electrode; and
a pair of a source region and a drain region formed in the main surface such that at least a channel region immediately under the first gate electrode is interposed therebetween,
wherein the first gate electrode is formed of a semiconductor layer containing an impurity of a first conductivity type,
wherein the second gate electrode is formed of a semiconductor layer containing an impurity of a second conductivity type,
wherein each of the source region and the drain region contains an impurity of the first conductivity type, and
wherein the source region includes a first source region, and a second source region having a concentration of the impurity of the first conductivity type higher than that of the first source region.

2. A semiconductor device according to claim 1,
wherein the first conductivity type is an n-type and the second conductivity type is a p-type.

3. A semiconductor device according to claim 1,
wherein the insulating film includes:
a first insulating film including a silicon oxide film;
a second insulating film including a silicon nitride film and covering an upper surface of the first insulating film; and
a third insulating film including a silicon oxide film and covering an upper surface of the second insulating film.

4. A semiconductor device according to claim 3,
wherein the third insulating film contains nitrogen.

5. A semiconductor device according to claim 1,
wherein the drain region includes:
a first drain region; and
a second drain region having a concentration of the impurity of the first conductivity type lower than that of the first drain region.

6. A semiconductor device according to claim 1, further comprising:
a source-side sidewall insulating film formed on a side of the second gate electrode where the source region is located so as to be adjacent to the second gate electrode,
wherein the first source region is located immediately under the source-side sidewall insulating film, and
wherein the second source region is located externally of the source-side sidewall insulating film.

7. A semiconductor device according to claim 5, further comprising:
a drain-side sidewall insulating film formed on a side of the first gate electrode where the drain region is located so as to be adjacent to the first gate electrode,
wherein the first drain region is located immediately under the drain-side sidewall insulating film, and
wherein the second drain region is located externally of the drain-side sidewall insulating film.

8. A semiconductor device according to claim 1,
wherein the second source region is located externally of the second gate electrode, and
wherein the first source region is located so as to come in contact with a lower surface of the second source region.

9. A semiconductor device according to claim 5,
wherein the second drain region is located externally of the first gate electrode, and
wherein the first drain region is located so as to come in contact with a lower surface of the second drain region.

10. A method of manufacturing a semiconductor device, comprising the steps of:
providing a semiconductor substrate having a main surface;
forming, over the main surface, a first gate electrode, and a dummy gate electrode adjacent to the first gate electrode;
forming a source region in the main surface using the dummy gate electrode as a mask;
removing the dummy gate electrode;
forming, over the main surface, a second gate electrode adjacent to the first gate electrode after the dummy gate electrode is removed; and
forming, in a state where the second gate electrode is covered, a drain region in a portion of the main surface which is located on a side of the first and second gate electrodes opposite to a side thereof where the source region is located,
wherein, in the step of forming the first gate electrode, an impurity of a first conductivity type is introduced into a semiconductor film intended to serve as the first gate electrode,
wherein, in the step of forming the second gate electrode, an impurity of a second conductivity type is introduced into a semiconductor film intended to serve as the second gate electrode,
wherein, in the steps of forming the source region and the drain region, an impurity of the first conductivity type is implanted into the semiconductor substrate, and
wherein the step of forming the source region includes the steps of:
forming a first source region; and
forming a second source region having a concentration of the impurity of the first conductivity type higher than that of the first source region.

11. A method of manufacturing a semiconductor device according to claim 10,
wherein the first conductivity type is an n-type and the second conductivity type is a p-type.

12. A method of manufacturing a semiconductor device according to claim 10, further comprising the step of:
forming an insulating film extending from a region interposed between the second gate electrode and the semiconductor substrate in continuous relation to a region interposed between the first gate electrode and the second gate electrode,
wherein the insulating film includes:
a first insulating film including a silicon oxide film;
a second insulating film including a silicon nitride film and covering an upper surface of the first insulating film; and
a third insulating film including a silicon oxide film and covering an upper surface of the second insulating film.

13. A method of manufacturing a semiconductor device according to claim 12,
wherein the third insulating film contains nitrogen.

14. A method of manufacturing a semiconductor device according to claim 10,
wherein the step of forming the drain region includes the steps of:
forming a first drain region; and
forming a second drain region having a concentration of the impurity of the first conductivity type higher than that of the first drain region.

15. A method of manufacturing a semiconductor device according to claim 10, further comprising the step of:
forming a dummy-source-side sidewall insulating film on a side of the dummy gate electrode where the source region is located such that the dummy-source-side sidewall insulating film is adjacent to the dummy gate electrode,
wherein, in the step of forming the first source region, the first source region is formed in the main surface using the dummy gate electrode as a mask, and
wherein, in the step of forming the second source region, the second source region is formed in the main surface using the dummy-source-side sidewall insulating film as a mask.

16. A method of manufacturing a semiconductor device according to claim 14, further comprising the step of:
forming a drain-side sidewall insulating film on a side of the first gate electrode where the drain region is located such that the drain-side sidewall insulating film is adjacent to the first gate electrode,
wherein, in the step of forming the first drain region, the first drain region is formed in the main surface using the first gate electrode as a mask, and
wherein, in the step of forming the second drain region, the second drain region is formed in the main surface using the drain-side sidewall insulating film as a mask.

17. A method of manufacturing a semiconductor device according to claim 14, further comprising the step of:
forming a drain-side sidewall insulating film on a side of the first gate electrode where the drain region is located such that the drain-side sidewall insulating film is adjacent to the first gate electrode,
wherein, in the step of forming the second drain region, the second drain region is formed in a portion of the main surface which is located externally of the first gate electrode using the drain-side sidewall insulating film as a mask, and
wherein, in the step of forming the first drain region, the first drain region is formed so as to come in contact with a lower surface of the second drain region using the drain-side sidewall insulating film as a mask.

18. A method of manufacturing a semiconductor device according to claim 10, further comprising the step of:
forming a dummy-source-side sidewall insulating film on a side of the dummy gate electrode where the source region is located such that the dummy-source-side sidewall insulating film is adjacent to the dummy gate electrode,
wherein, in the step of forming the second source region, the second source region is formed in the main surface using the dummy-source-side sidewall insulating film as a mask,
wherein, in the step of forming the first source region, the first source region is formed so as to come in contact with a lower surface of the second source region using the dummy-source-side sidewall insulating film as a mask,
wherein the step of forming the source region further includes the step of:
forming a third source region other than the first and second source regions, and
wherein, in the step of forming the third source region, the third source region is formed in the main surface using the dummy gate electrode as a mask.
